(19) United States
(12) Patent Application Publication
(10) Pub. No.: US 2007/0038908 A1
(43) Pub. Date: Feb. 15, 2007

(54) Design data structure for semiconductor integrated circuit and apparatus and method for designing the same

(76) Inventors: Yoko Hirano, Kyoto (JP); Katsuya Fujimura, Kyoto (JP); Aya Mototani, Osaka (JP); Sadami Takeoka, Osaka (JP)

Correspondence Address: MCDERMOTT WILL & EMERY LLP, 600 13TH STREET, N.W., WASHINGTON, DC, 20005-3096, US

(21) Appl. No.: 11/378,396

(22) Filed: Mar. 20, 2006

(30) Foreign Application Priority Data
Aug. 1, 2005 (JP) 2005-222479

(51) Int. Cl. G01R 31/28

(52) U.S. Cl. 714/724

(57) ABSTRACT

Design data including circuit data on a test point and information about a test mode, which has been attached to the test point, is inputted to an apparatus for designing a semiconductor integrated circuit. A design data code analysis unit in a data input unit performs the code analysis of the design data and, after the code analysis, the resulting design data is stored by a database storage unit in a storage device. A test point deletion unit receives the test mode specified from the outside and deletes data on an unnecessary test point from the design data stored in the storage device. The design data which does not include the unnecessary test point is outputted from a data output unit. Accordingly, even when the test mode is changed, there is no need to calculate the test efficiency again in response to each change or add the step of inserting a new test point.

### CROSS REFERENCE TO RELATED APPLICATIONS

This Non-provisional application claims priority under 35 U.S.C. §119(a) on Patent Application No. 2005-222479 filed in Japan on Aug. 1, 2005, the entire contents of which are hereby incorporated by reference.

### BACKGROUND OF THE INVENTION

The present invention relates to a design data structure for improving test efficiency in design for testability for a semiconductor integrated circuit and to an apparatus and method for design.

In design for testability for a semiconductor integrated circuit, a method has been known which improves test efficiency by adding a test point.

For example, a method for improving testability comprises the steps of calculating the controllability, monitorability, and fault detection probability of each node, selecting the fault of a specified node, and adding a flip-flop as a test point when each of the respective values of the controllability, monitorability, and fault detectability does not fall within a prescribed range so that the testability has not reached a prescribed level. The technology is disclosed in, e.g., Japanese Laid-Open Patent Publication No. HEI 6-331709.

In the case of using a logic BIST approach as a test mode which performs a scan test by using a random pattern, a flip-flop as a test point is added to a portion with a low probability of becoming 0 or 1 by assuming a random application of the test pattern, thereby increasing the probability of becoming 0 or 1 and compensating for a demerit resulting from the characteristic of the random pattern. Thus, the method which adds the test point to improve the transition probability has been reported. The technology is disclosed in, e.g., the document entitled “LOW OVERHEAD TEST POINT INSERTION FOR SCAN-BASED BIST”, ITC (INTERNATIONAL TEST CONFERENCE 1999), which is written by Michinobu Nakao and the other four persons.

Thus, a test point is added for a purpose which differs according to a test mode.

In the test point design disclosed in the patent publication or document shown above, every time the test mode changes in actual design, a transition should be made to a design flow which adds a test point as necessary. In the present situation where design resource diversion and IP design distribution have been incorporated in normal design, the repetitive transitions partly account for useless design steps.

FIG. 25 shows a conventional test point design flow in which an RTL design data D001 is inputted and logically synthesized in Logic Synthesis Step S001 so that a net list is generated. Then, to enhance the test efficiency of a test mode D002 specified by a computer to the net list, the test efficiency is calculated in Test Efficiency Calculation Step S002. From the result of calculating the test efficiency, a test-point-insertion node as a target of test point insertion necessary for enhancing the test efficiency is determined. Subsequently, in Test Point Insertion Step S003, insertion of a test point is performed with respect to the test-point-insertion node determined in Test Effect Calculation Step S002, whereby a net list D003 including the test point is generated.

In the design flow, even though the content of the input RTL design data D001 is not changed at all or is changed only slightly, it is necessary to perform Test Efficiency Calculation Step S002. In IP and core design used for a plurality of semiconductor integrated circuits, after test point insertion has thus been accomplished, Step S002 mentioned above is a step which can be omitted through design resource diversion and it can be considered that a reduction in design TAT is achievable.

### SUMMARY OF THE INVENTION

It is therefore an object of the present invention to implement design in which, even when a test mode is changed, the change is compensated for without calculating again the test efficiency in response to each change in the test mode or without adding the step of inserting a new test point based on the result of calculating the test efficiency and thereby reduce the number of design steps.

To attain the object, the present invention preliminarily adds circuit data on test points applied to design for testability to data on a semiconductor integrated circuit included in input design data and also adds various information about a test mode thereto in association with the circuit data on the test points such that, when the necessity arises to change the test mode in actual design, the change in the test mode is compensated for by leaving only the test point at which given information included in the information about the test mode used thereat satisfies a specified condition and deleting an unnecessary test point at which the specified condition is not satisfied.

Specifically, a design data structure for a semiconductor integrated circuit according to the present invention is a design data structure for use in design of a semiconductor integrated circuit using a computer, the design data structure comprising: circuit data on at least one test point added to a specified node in the semiconductor integrated circuit as a target of design for testability; and information about at least one test mode associated with the circuit data on the test point to validate the test point, wherein when the computer specifies the test mode which satisfies a specified condition for given information included in the information about the test mode, an unnecessary test point which does not have the given information satisfying the specified condition is invalidated.

An apparatus for designing a semiconductor integrated circuit according to the present invention is an apparatus for designing a semiconductor integrated circuit using the design data structure mentioned above, the apparatus comprising: a data input unit comprising a design data code analysis unit for reading the design data structure and analyzing a code of design data included in the design data structure and composed of the circuit data on the semiconductor integrated circuit and on the test point and of the information about the test mode and a database storage unit for storing a result of the analysis by the design data code analysis unit in a database; a test point deletion unit for deleting the unnecessary test point at which the specified condition indicated by the computer is not satisfied from the result of the analysis stored in the database; and a circuit data output unit for outputting circuit data on the test point remaining as a result of the deletion of the unnecessary test point by the test point deletion unit and on the semiconductor integrated circuit.

An apparatus for designing a semiconductor integrated circuit according to the present invention is an apparatus for designing a semiconductor integrated circuit using the design data structure mentioned above, the apparatus comprising: a data input unit comprising a design code analysis unit for reading the design data structure and analyzing a code of design data included in the design data structure and composed of the circuit data on the semiconductor integrated circuit and on the test point and of the information about the test mode, a test point deletion unit for deleting the unnecessary test point at which the specified condition indicated by the computer is not satisfied from a result of the analysis by the design data code analysis unit, and a database storage unit for storing a result of the deletion in a database; and a circuit data output unit for outputting the circuit data on the test point remaining as the result of the deletion of the unnecessary test point by the test point deletion unit and on the semiconductor integrated circuit which has been stored in the database by the database storage unit.

An embodiment of the apparatus for designing a semiconductor integrated circuit according to the present invention further comprises: a logic synthesis unit for performing a logic synthesis process with respect to the circuit data on the semiconductor integrated circuit and on the test point which has been stored in the database and storing a result of the logic synthesis process in the database.

An embodiment of the apparatus for designing a semiconductor integrated circuit according to the present invention further comprises: a logic synthesis unit for performing a logic synthesis process with respect to the circuit data on the semiconductor integrated circuit and on the test point which has been stored in the database and storing a result of the logic synthesis process in the database.

A method for designing a semiconductor integrated circuit according to the present invention is a method for designing a semiconductor integrated circuit using the design data structure mentioned above, the method comprising: a circuit data read step including a design data code analysis step of reading the design data structure and analyzing a code of design data included in the design data structure and composed of the circuit data on the semiconductor integrated circuit and on the test point and of the information about the test mode and a database storage step of storing a result of the analysis by the design data code analysis step in a database; a test point deletion step of deleting the unnecessary test point at which the specified condition indicated by the computer is not satisfied from the result of the analysis stored in the database; and a circuit data output step of outputting circuit data on the test point remaining as a result of the deletion of the unnecessary test point by the test point deletion step and on the semiconductor integrated circuit.

A method for designing a semiconductor integrated circuit according to the present invention is a method for designing a semiconductor integrated circuit using the design data structure described above, the method comprising: a circuit data read step including a design code analysis step of reading the design data structure and analyzing a code of design data included in the design data structure and composed of the circuit data on the semiconductor integrated circuit and on the test point and of the information about the test mode, a test point deletion step of deleting the unnecessary test point at which the specified condition indicated by the computer is not satisfied from a result of the analysis by the design data code analysis step, and a database storage step of storing a result of the deletion in a database; and a circuit data output step of outputting the circuit data on the test point remaining as the result of the deletion of the unnecessary test point in the test point deletion step and on the semiconductor integrated circuit which has been stored in the database in the database storage step.

A method for designing a semiconductor integrated circuit according to the present invention is a method for designing a semiconductor integrated circuit using the design data structure mentioned above, the method comprising: a circuit data read step including a design data code analysis step of reading the design data structure and analyzing a code of design data included in the design data structure and composed of the circuit data on the semiconductor integrated circuit and on the test point and of the information about the test mode and a database storage step of storing a result of the analysis by the design data code analysis step in a database; a test point deletion step of deleting the unnecessary test point at which the specified condition indicated by the computer is not satisfied from the result of the analysis stored in the database; a logic synthesis step of performing a logic synthesis process with respect to circuit data on the test point remaining as a result of the deletion of the unnecessary test point in the test point deletion step and on the semiconductor integrated circuit; and a circuit data output step of outputting the circuit data on the remaining test point and on the semiconductor integrated circuit to which the logic synthesis process has been performed in the logic synthesis step.

A method for designing a semiconductor integrated circuit according to the present invention is a method for designing a semiconductor integrated circuit using the design data structure mentioned above, the method comprising: a circuit data read step including a design code analysis step of reading the design data structure and analyzing a code of design data included in the design data structure and composed of the circuit data on the semiconductor integrated circuit and on the test point and of the information about the test mode, a test point deletion step of deleting the unnecessary test point at which the specified condition indicated by the computer is not satisfied from a result of the analysis in the design data code analysis step, and a database storage step of storing a result of the deletion in a database; a logic synthesis step of performing a logic synthesis process with respect to circuit data on the test point remaining as a result of the deletion of the unnecessary test point in the test point deletion step and stored in the database in the database storage step and on the semiconductor integrated circuit; and a circuit data output step of outputting the circuit data on the remaining test point and on the semiconductor integrated circuit to which the logic synthesis process has been performed in the logic synthesis step.

In an embodiment of the design data structure for a semiconductor integrated circuit according to the present invention, the information about the test mode includes type information indicative of a type of the test mode associated with the circuit data on the test point and the computer specifies the test mode of a specified type in respect of the type information included in the information about the test mode and invalidates the unnecessary test point which does not correspond to the test mode having the type information of the specified type.

In an embodiment of the method for designing a semiconductor integrated circuit according to the present invention, the information about the test mode includes type information indicative of a type of the test mode associated with the circuit data on the test point and the test point deletion step includes deleting, when the computer specifies the test mode showing a specified type in respect of the type information, the unnecessary test point for the test mode which does not include the type information of the specified type that has been specified by the computer.

In an embodiment of the design data structure for a semiconductor integrated circuit according to the present invention, the information about the test mode includes effect information indicative of an effect associated with the circuit data on the test point and suited to a use purpose of the test mode and the computer specifies the test mode having a specified effect in respect of the effect information included in the information about the test mode and invalidates the unnecessary test point which does not correspond to the test mode having the effect information showing the specified effect.

In an embodiment of the method for designing a semiconductor integrated circuit according to the present invention, the test point deletion step includes deleting the test point having a small effect compared with an area increase based on effect information included in the test point.

In an embodiment of the design data structure for a semiconductor integrated circuit according to the present invention, the information about the test mode includes indication information associated with the circuit data on the test point and indicative of whether or not the test point may be automatically deleted and when the computer specifies indication information permitting the automatic deletion in respect of the indication information included in the information about the test mode, the unnecessary test point corresponding to the test mode including the specified indication information is invalidated.

In an embodiment of the method for designing a semiconductor integrated circuit according to the present invention, the test point deletion step includes deleting the test point having a small effect compared with an area increase based on the indication information on whether or not the test point may be automatically deleted.

In an embodiment of the design data structure for a semiconductor integrated circuit according to the present invention, the information about the test mode includes weighting information which is information associated with the circuit data on the test point and related to the plurality of test points in each of which it is included and when the computer specifies the test mode which does not include given weighting information in respect of the weighting information included in the information about the test mode, the unnecessary test point corresponding to the specified test mode is invalidated.

In an embodiment of the method for designing a semiconductor integrated circuit according to the present invention, the information about the test mode includes weighting information which is information associated with the circuit data on the test point and related to the plurality of test points in each of which it is included and the test point deletion step includes deleting the test point corresponding to the test mode of which the weighting information does not include given weighting information specified by the computer.

In an embodiment of the design data structure for a semiconductor integrated circuit according to the present invention, the computer optimizes the test point corresponding to the test mode having the given information which satisfies the specified condition indicated thereby.

An apparatus for designing a semiconductor integrated circuit according to the present invention is an apparatus for designing a semiconductor integrated circuit using the design data structure mentioned above, the apparatus comprising: a data input unit comprising a design data code analysis unit for reading the design data structure and analyzing a code of design data included in the design data structure and composed of the circuit data on the semiconductor integrated circuit and on the test point and of the information about the test mode and a database storage unit for storing a result of the analysis by the design data code analysis unit in a database; a test point deletion unit for deleting the unnecessary test point at which the specified condition indicated by the computer is not satisfied from the result of the analysis stored in the database; a logic synthesis unit for performing a logic synthesis process involving optimization of the test point corresponding to the test mode having the given information which satisfies the specified condition indicated by the computer and storing a result of the logic synthesis process in the database; and a circuit data output unit for outputting, from the database, the circuit data on the test point remaining as a result of the deletion of the unnecessary test point by the test point deletion unit and on the semiconductor integrated circuit.

An apparatus for designing a semiconductor integrated circuit according to the present invention is an apparatus for designing a semiconductor integrated circuit using the design data structure mentioned above, the apparatus comprising: a data input unit comprising a design code analysis unit for reading the design data structure and analyzing a code of design data included in the design data structure and composed of the circuit data on the semiconductor integrated circuit and on the test point and of the information about the test mode, a test point deletion unit for deleting the unnecessary test point at which the specified condition indicated by the computer is not satisfied from a result of the analysis by the design data code analysis unit, and a database storage unit for storing a result of the deletion in a database; a logic synthesis unit for performing a logic synthesis process involving optimization of the test point corresponding to the test mode having the given information which satisfies the specified condition indicated by the computer and storing a result of the logic synthesis process in the database; and a circuit data output unit for outputting, from the database, the circuit data on the test point remaining as the result of the deletion of the unnecessary test point by the test point deletion unit and on the semiconductor integrated circuit which has been stored in the database by the database storage unit.

A method for designing a semiconductor integrated circuit according to the present invention is a method for designing a semiconductor integrated circuit using the design data structure mentioned above, the method comprising: a circuit data read step including a design data code analysis step of reading the design data structure and analyzing a code of design data included in the design data structure and composed of the circuit data on the semiconductor integrated circuit and on the test point and of the information about the test mode and a database storage step of storing a result of the analysis by the design data code analysis step in a database; a test point deletion step of deleting the unnecessary test point at which the specified condition indicated by the computer is not satisfied from the result of the analysis stored in the database; a logic synthesis step of performing a logic synthesis process involving optimization of the test point corresponding to the test mode having the given information which satisfies the specified condition indicated by the computer and storing a result of the logic synthesis process in the database; and a circuit data output step of outputting, from the database, the circuit data on the test point remaining as a result of the deletion of the unnecessary test point by the test point deletion step and on the semiconductor integrated circuit.

A method for designing a semiconductor integrated circuit according to the present invention is a method for designing a semiconductor integrated circuit using the design data structure mentioned above, the method comprising: a circuit data read step including a design code analysis step of reading the design data structure and analyzing a code of design data included in the design data structure and composed of the circuit data on the semiconductor integrated circuit and on the test point and of the information about the test mode, a test point deletion step of deleting the unnecessary test point at which the specified condition indicated by the computer is not satisfied from a result of the analysis in the design data code analysis step, and a database storage step of storing a result of the deletion in a database; a logic synthesis step of performing a logic synthesis process involving optimization of the test point corresponding to the test mode having the given information which satisfies the specified condition indicated by the computer and storing a result of the logic synthesis process in the database; and a circuit data output step of outputting, from the database, the circuit data on the test point remaining as the result of the deletion of the unnecessary test point by the test point deletion step and on the semiconductor integrated circuit which has been stored in the database by the database storage step.

An embodiment of the design data structure for a semiconductor integrated circuit according to the present invention includes positional information associated with the circuit data on the test point and showing a position of the test point, wherein the computer performs optimization of the test point corresponding to the test mode having the given information which satisfies the specified condition by using the positional information on the test point.

An embodiment of the method for designing a semiconductor integrated circuit according to the present invention includes positional information associated with the circuit data on the test point and showing a position of the test point, wherein the logic synthesis step includes performing the logic synthesis process involving optimization through merging of the test point corresponding to the test mode having the given information which satisfies the specified condition by using the positional information on the test point.

In an embodiment of the design data structure for a semiconductor integrated circuit according to the present invention, the information about the test mode includes clock frequency information associated with the circuit data on the test point and the computer performs optimization of the test point based on the clock frequency information.

In an embodiment of the method for designing a semiconductor integrated circuit according to the present invention, the information about the test mode includes clock frequency information associated with the circuit data on the test point and the logic synthesis step includes performing the logic synthesis process involving optimization through sharing of a clock source based on the clock frequency information.

In an embodiment of the method for designing a semiconductor integrated circuit according to the present invention, the information about the test mode includes logic synthesis constraint information associated with the circuit data on the test point and the computer performs optimization of the test point based on the logic synthesis constraint information.

In an embodiment of the method for designing a semiconductor integrated circuit according to the present invention, the information about the test mode is associated with the circuit data on the test point and includes logic synthesis constraint information on the test point and the logic synthesis step includes performing the logic synthesis process involving optimization of timing based on the logic synthesis constraint information.

Thus, one aspect of the invention is the design data structure for a semiconductor integrated circuit which includes not only the circuit data on the semiconductor integrated circuit but also the circuit data on the test point and the information about the test mode in association with the test point. This obviates the necessity to perform the step of calculating the test efficiency and insert a necessary test point every time the test mode is changed, allows compensation for the change only by judging and deleting an unnecessary test point based on a specified condition for given information in the information about the test mode which is included in the test point, and thereby allows a reduction in the number of design steps.

Another aspect of the invention is the apparatus for designing a semiconductor integrated circuit which receives the design data on a semiconductor integrated circuit and a specified test mode from the outside such that the design data code analysis unit of the data input unit performs the code analysis of the design code and the data storage unit stores the result of the analysis in the storage device. In the test point deletion unit, an unnecessary test point is deleted based on the test mode received from the outside so that the design data from which the unnecessary test point has been deleted is outputted from the data output unit.

Still another aspect of the invention is the method for designing a semiconductor integrated circuit which is implemented by using the apparatus for designing a semiconductor integrated circuit.

In accordance with the present aspects of the invention, it becomes possible to generate the design data for a semiconductor integrated circuit which includes only a necessary test point by omitting the step of calculating test efficiency calculation and inserting a test point and thereby reduce the number of design steps.

Yet another aspect of the invention is the apparatus for designing a semiconductor integrated circuit which has the test point deletion unit provided in the data input unit so that the design data from which the unnecessary test point has been deleted by the test point deletion unit is stored in the storage device.

Still another aspect of the invention is the method for designing a semiconductor integrated circuit which implements the storage of the design data in the storage device after deleting the unnecessary test point by using the apparatus for designing a semiconductor integrated circuit.

In contrast to the above-mentioned aspects of the invention, the apparatus and method for designing a semiconductor integrated circuit according to the present aspects of the invention delete the unnecessary test point before storing the information in the storage device. Accordingly, the test point once deleted cannot be recovered any more but the advantage is offered that a used space in the memory is reduced.

Yet another aspect of the invention is the apparatus for designing a semiconductor integrated circuit in which the logic synthesis is performed in the logic synthesis unit after the process in the test point deletion unit.

Still another aspect of the invention is the method for designing a semiconductor integrated circuit which implements the logic synthesis process after the deletion of the unnecessary test point by using the apparatus for designing a semiconductor integrated circuit.

In accordance with the present aspects of the invention, it becomes possible to omit the step of calculating the test efficiency and inserting the test point and thereby generate gate-level design data for a semiconductor integrated circuit which includes only a necessary test point by using the design data structure.

Yet another aspect of the invention is the apparatus for designing a semiconductor integrated circuit in which logic synthesis is performed in the logic synthesis unit after the process in the database storage unit.

Still another aspect of the present is the method for designing a semiconductor integrated circuit which is implemented by using the apparatus for designing a semiconductor integrated circuit.

In contrast to the above-mentioned aspect of the invention, the apparatus and method for designing a semiconductor integrated circuit according to the present aspects of the invention delete the unnecessary test point before storing the information in the storage device. Accordingly, the test point once deleted cannot be recovered any more but the advantage is offered that a used space in the memory is reduced.

Yet another aspect of the invention is the design data structure for a semiconductor integrated circuit which has type information on the test mode for validating the test point as information for invalidating an unnecessary test point for the specified test mode or rendering it deletable.

Still another aspect of the invention is the method for designing a semiconductor integrated circuit which deletes the unnecessary test point by using the type information on the test mode for validating the test point included in the design data structure for a semiconductor integrated circuit.

In accordance with the present aspects of the invention, it becomes possible to delete the test point which is valid for a test mode other than the specified one.

Yet another aspect of the invention is the design data structure for a semiconductor integrated circuit which has the effect information on the test point as information for invalidating the unnecessary test point for the specified test mode or rendering it deletable.

Still another aspect of the invention is the method for designing a semiconductor integrated circuit which deletes the unnecessary test point by using the effect information on the test point included in the design data structure for a semiconductor integrated circuit.

Since the present aspect of the invention allows the deletion of the test point having a small effect even though it is valid for the specified test mode, it becomes possible to reduce the circuit area compared with the method for designing a semiconductor integrated circuit according to the above-mentioned aspect.

Yet another aspect of the invention is the design data structure for a semiconductor integrated circuit which has automatic deletion prohibition information on the test point as information for invalidating the unnecessary test point for the specified test mode or rendering it deletable.

Still another aspect of the invention is the method for designing a semiconductor integrated circuit which can prevent the deletion of the test point even when it is judged to be unnecessary by using the automatic deletion prohibition information included in the test point.

Even when the test point inserted to improve the test quality is less effective as the test point, the present aspects of the invention allow the test point to be left without deleting it.

Yet another aspect of the invention is the design data structure for a semiconductor integrated circuit which has the weighting information related to the plurality of test points in each of which it is included as information for invalidating the unnecessary test point for the specified test mode or rendering it deletable.

Still another aspect of the invention is the method for designing a semiconductor integrated circuit which deletes the unnecessary test point by using the weighting information related to the plurality of test points in each of which it is included.

In accordance with the present aspects of the invention, it becomes possible to evaluate the effect of the plurality of test points which is achievable when they are used in combination and thereby efficiently leave the test points.

Yet another aspect of the invention is the design data structure for a semiconductor integrated circuit which comprises a test point for one or a plurality of test modes for the semiconductor integrated circuit to allow effective use thereof and circuit optimization therefor, wherein the test point includes information for invalidating the unnecessary test point for a specified test mode or rendering it deletable and information for optimizing the test point. This provides the design data structure for a semiconductor integrated circuit which has the optimization function for invalidating the unnecessary test point in accordance with the specified test mode. This allows further circuit optimization compared with the design data structure according to the above-mentioned aspect.

Still another aspect of the invention is the apparatus for designing a semiconductor integrated circuit comprising the process of optimizing a test point circuit as the process in the logic synthesis unit.

Yet another aspect of the invention is the method for designing a semiconductor integrated circuit which is implemented by using the apparatus for designing a semiconductor integrated circuit.

In accordance with the present aspects of the invention, it becomes possible to allow the method for designing a semiconductor integrated circuit using the apparatus for designing a semiconductor integrated circuit to perform the process of optimizing the test point circuit.

Still another aspect of the invention is the apparatus for designing a semiconductor integrated circuit which performs the process of optimizing the test point circuit as the process in the logic synthesis unit.

Yet another aspect of the invention is the method for designing a semiconductor integrated circuit which is implemented by using the apparatus for designing a semiconductor integrated circuit.

The present aspect of the invention allows the method for designing a semiconductor integrated circuit using the apparatus for designing a semiconductor integrated circuit to perform the process of optimizing the test point circuit by using the design data structure for a semiconductor integrated circuit.

Yet another aspect of the invention is the design data structure for a semiconductor integrated circuit which has positional information on the test point as information for optimizing the test point in accordance with the specified test mode.

Still another aspect of the invention is the method for designing a semiconductor integrated circuit which allows a mergeable test point to be merged by using the positional information on the test point included in the designing data structure for a semiconductor integrated circuit.

In accordance with the present aspects of the invention, it becomes possible to reduce the circuit area without reducing the effect of the test point.

Yet another aspect of the invention is the design data structure for a semiconductor integrated circuit which has clock frequency information on the test point as information for optimizing the test point in accordance with the specified test mode.

Still another aspect of the invention is the method for designing a semiconductor integrated circuit which allows a sharable clock source to be shared by using the clock frequency information for controlling the test point included in the design data structure for a semiconductor integrated circuit.

In accordance with the present aspects of the invention, it becomes possible to simplify the test point control circuit and perform easy timing adjustment of the clock connected to the test point.

Yet another aspect of the invention is the design data structure for a semiconductor integrated circuit which has timing constraint information on the test point as information for optimizing the test point in accordance with the specified test mode.

The present aspect of the invention also allows timing optimization of the test point circuit by using the timing constraint information on the test point included in the design data structure for a semiconductor integrated circuit.

In accordance with the present aspect of the invention, it becomes possible to perform easy timing optimization of the entire circuit including the test point.

### BRIEF DESCRIPTION OF THE DRAWINGS

FIG. 1 is a circuit diagram showing circuit data on a semiconductor integrated circuit including test points for one or a plurality of test modes according to a first embodiment of the present invention;

FIG. 2 is a view showing information on the test points for the semiconductor integrated circuit including the test points for the one or plurality of test modes according to the first embodiment;

FIG. 3 is a view showing the information on the test points for the semiconductor integrated circuit including the test points for the one or plurality of test modes according to the first embodiment;

FIG. 4 is a view showing an apparatus for designing the semiconductor integrated circuit according to the first embodiment;

FIG. 5 is a view showing an apparatus for designing a semiconductor integrated circuit according to a second embodiment of the present invention;

FIG. 6 is a view showing an apparatus for designing a semiconductor integrated circuit according to a third embodiment of the present invention;

FIG. 7 is a view showing an apparatus for designing a semiconductor integrated circuit according to a fourth embodiment of the present invention;

FIG. 8 is a flow chart diagram showing a method for designing the semiconductor integrated circuit according to the first embodiment;

FIG. 9 is a flow chart diagram showing a method for designing a semiconductor integrated circuit according to the second embodiment;

FIG. 10 is a flow chart diagram showing a method for designing a semiconductor integrated circuit according to the third embodiment;

FIG. 11 is a flow chart diagram showing a method for designing a semiconductor integrated circuit according to the fourth embodiment;

FIG. 12 is a circuit diagram showing data on a semiconductor integrated circuit obtained by deleting an unneeded one of the test points from the semiconductor integrated circuit of FIG. 1;

FIG. 13 is a circuit diagram showing data for a semiconductor integrated circuit obtained by deleting an unneeded one of the test points from the semiconductor integrated circuit of FIG. 1;

FIG. 14 is a view showing an apparatus for designing a semiconductor integrated circuit according to a fifth embodiment of the present invention;

FIG. 15 is a view showing an apparatus for designing a semiconductor integrated circuit according to a sixth embodiment of the present invention;

FIG. 16 is a flow chart diagram showing a method for designing a semiconductor integrated circuit according to the fifth embodiment;

FIG. 17 is a flow chart diagram showing a method for designing a semiconductor integrated circuit according to the sixth embodiment;

FIG. 18 is a circuit diagram showing circuit data on a semiconductor integrated circuit including test points for one or a plurality of test modes according to the fifth embodiment;

FIG. 19 is a view showing information on the test points in the semiconductor integrated circuit including the test points for the one or plurality of test modes according to the fifth embodiment;

FIG. 20 is a view showing information on the test points in the semiconductor integrated circuit including the test points for the one or plurality of test modes according to the fifth embodiment;

FIG. 21 is a view showing coordinates in positional information on the test points in the semiconductor integrated circuit including the test points for the one or plurality of test modes according to the fifth embodiment;

FIG. 22 is a circuit diagram showing data on a semiconductor integrated circuit resulting from the merging of a mergeable one of the test points in the semiconductor integrated circuit of FIG. 18;

FIG. 23 is a circuit diagram showing circuit data for a semiconductor integrated circuit resulting from the sharing of a sharable clock input among the test points in the semiconductor integrated circuit of FIG. 18;

FIG. 24 is a circuit diagram showing data on a semiconductor integrated circuit obtained by deleting the unneeded one of the test points from the semiconductor integrated circuit of FIG. 1; and

FIG. 25 is a flow chart diagram of conventional test point design.

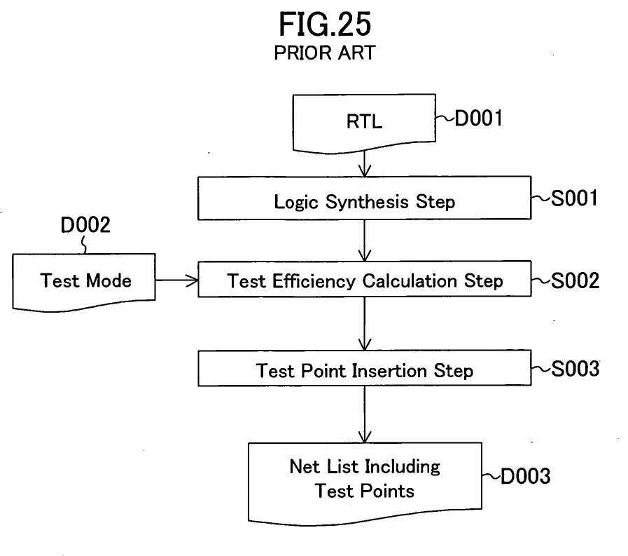

### DETAILED DESCRIPTION OF THE INVENTION

Referring to the drawings, the embodiments of the present invention will be described herein below in detail.

### Embodiment 1

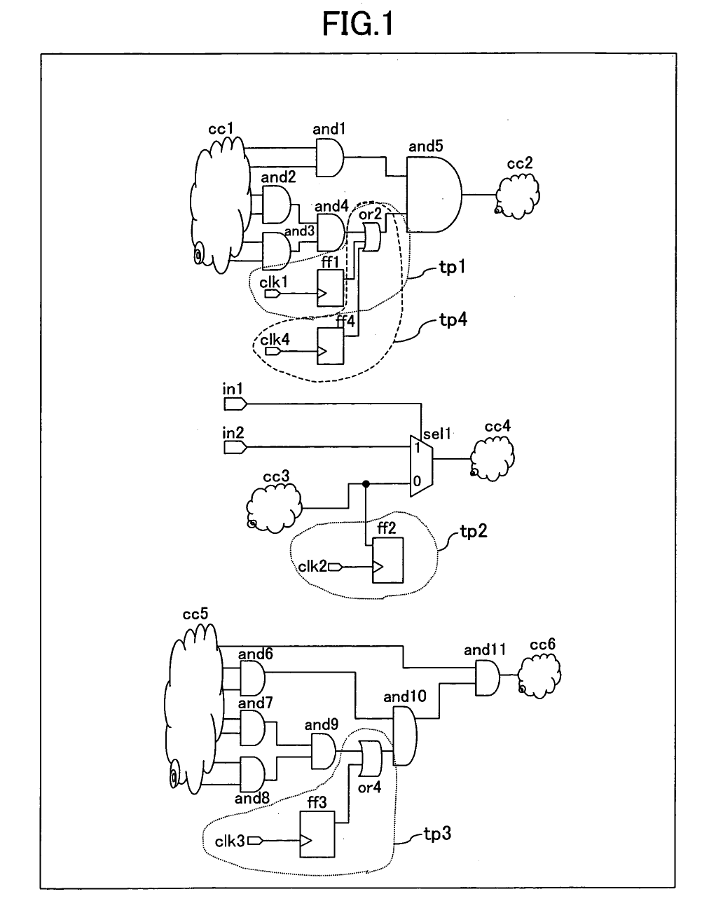

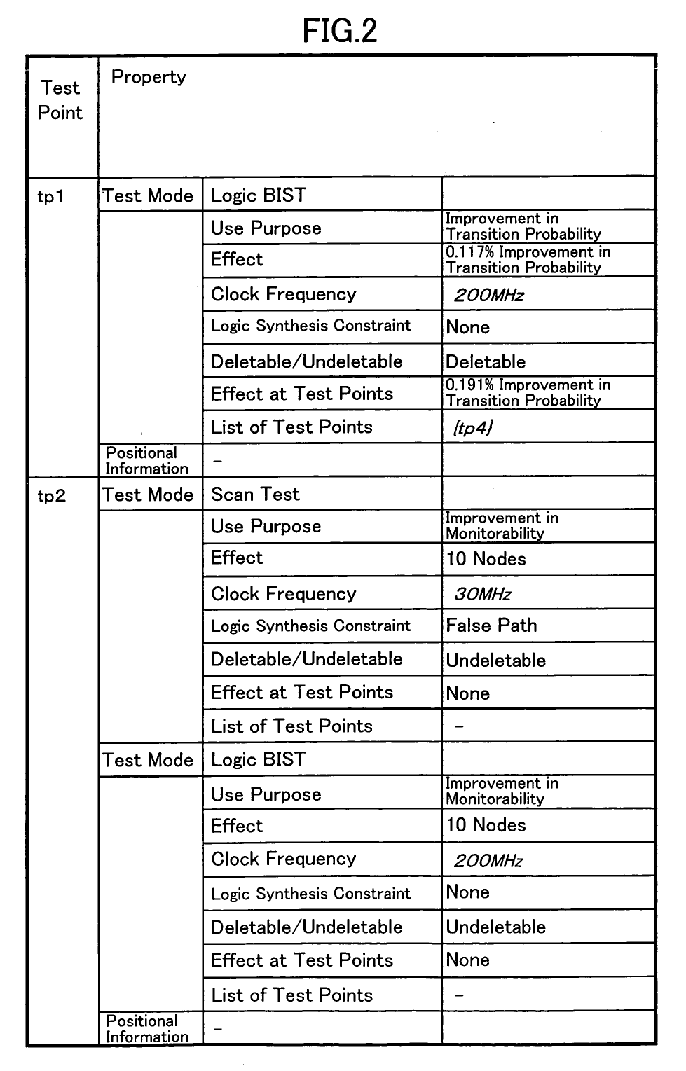

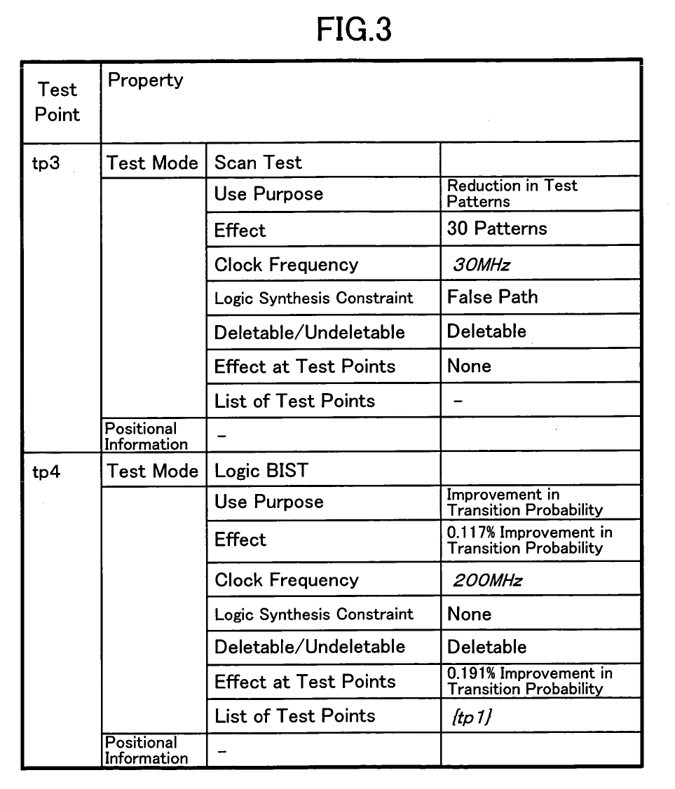

FIG. 1 shows circuit data on a semiconductor integrated circuit including test points for implementing a test mode for design for testability (hereinafter simply referred to as circuit data) according to the first embodiment of the present invention. FIGS. 2 and 3 show information (information about the test mode) attached to circuit data on the test points (hereinafter simply referred to as the test points) that has been added to the circuit data on the semiconductor integrated circuit. As shown in FIG. 1, at least one test point is added to a specified node of which design for testability is required in the semiconductor integrated circuit.

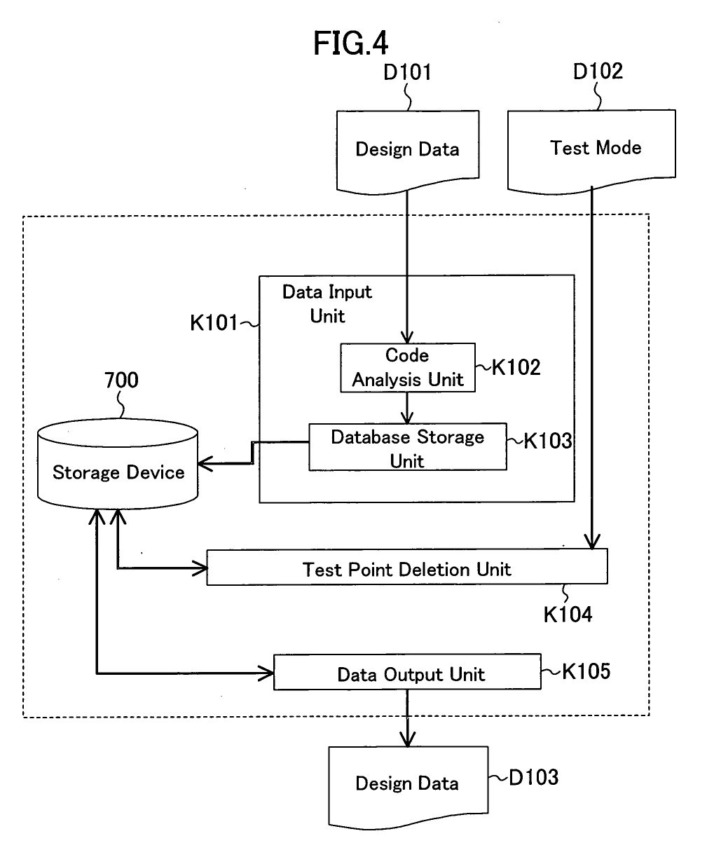

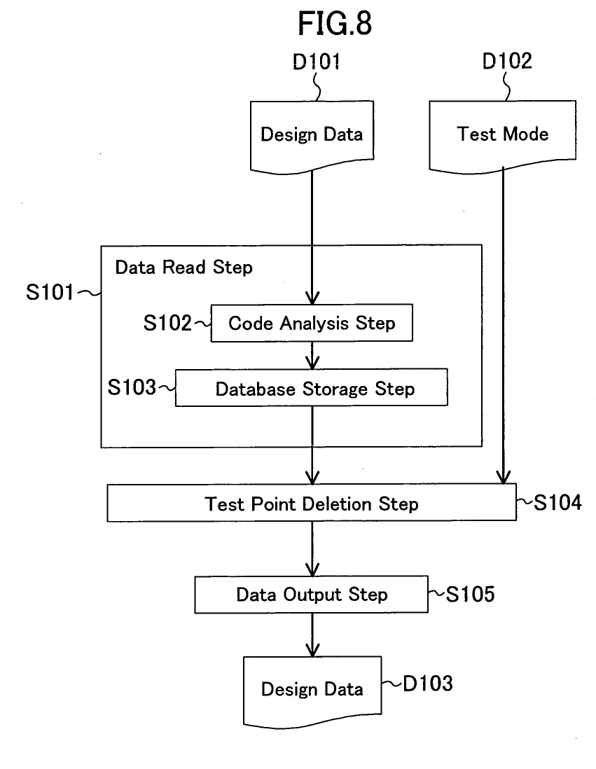

FIG. 4 shows an apparatus for designing the semiconductor integrated circuit according to the first embodiment. FIG. 8 is a flow chart diagram showing a method for designing the semiconductor integrated circuit by using the apparatus for designing the semiconductor integrated circuit. The circuit data, the test points in the circuit data, and the information attached to the test points are combined to provide design data.

The group of combinational circuits shown in FIG. 1 include: six combinational circuits cc1 to cc6; two OR circuits or2 and or4; eleven AND circuits and1 to and11; a selector sel1; four flip-flops ff1 to ff4; and six input terminals in1, in2, and clk1 to clk4.

A description will be given first to the circuit structure between the combinational circuits cc1 and cc2 in the semiconductor integrated circuit shown in FIG. 1. To each of the inputs of the AND circuits and1 to and3, the output of the combinational circuit cc1 is connected. To the inputs of the AND circuit and4, the respective outputs of the AND circuits and2 and and3 are connected. To the clock input of the flip-flop ff1, the input terminal clk1 is connected. To the inputs of the OR circuit or2, the output of the AND circuit and4, the output of the flip-flop ff1, and the output of the flip-flop ff4 are connected.

To the inputs of the AND circuit and5, the output of the AND circuit and1 and the output of the OR circuit or2 are connected. To the node between the output of the AND circuit and4 and one of the inputs of the AND circuit and5, a test point tp1 composed of the flip-flop ff1, the OR circuit or2, and the input terminal clk1 is added. A test point tp4 composed of the flip-flop ff4, the OR circuit or2, and the input terminal clk4 is also added to the same node.

A description will be given next to the circuit structure between the combinational circuits cc3 and cc4. The selector sel1 is controlled by the input terminal in1 such that, when the input value of the input terminal in1 is 1, the input terminal in2 is selected and that, when the input value thereof is 0, the output value of the combinational circuit cc3 is selected. To the clock input of the flip-flop ff2, the input terminal clk2 is connected. To the input of the combinational circuit cc4, the output of the selector sel1 is connected. To the node between the output of the combinational circuit cc3 and the 0-input of the selector sel1, a test point tp2 composed of the flip-flop ff2 and the input terminal clk2 is added.

Subsequently, a description will be given to the circuit structure between the combinational circuits cc5 and cc6. To each of the respective inputs of the AND circuits and6, and7, and and8, the output of the combinational circuit cc5 is connected. To the inputs of the AND circuit and9, the respective outputs of the AND circuits and7 and and8 are connected. To the clock input of the flip-flop ff3, the input terminal clk3 is connected.

To the inputs of the OR circuit or4, the output of the AND circuit and9 and the output of the flip-flop ff3 are connected. To the inputs of the AND circuits and10, the output of the AND circuit and6 and the output of the OR circuit or4 are connected. To the inputs of the AND circuit and11, the output of the combinational circuit cc5 and the output of the AND circuit and10 are connected. To the input of the combinational circuit cc6, the output of the AND circuit and11 is connected. To the node between the output of the AND circuit and9 and one of the inputs of the AND circuit and10, a test point tp3 composed of the flip-flop ff3, the input terminal clk3, and the OR circuit or4 is added.

FIG. 2 shows information attached to the test points tp1 and tp2 added to the circuit data. FIG. 3 shows information attached to the test points tp3 and tp4 added to the circuit data. Each of the test points tp1 to tp4 holds “Test Mode” and “Positional Information” as information (information about a test mode) associated therewith. For each “Test Mode”, information composed of the “Type”, “Use Purpose”, “Effect”, “Clock Frequency”, “Logic Synthesis Constraint”, “Deletable/Undeletable”, “Effect at Test Points”, and “List of Test Points” is also held.

A description will be given next to the test points tp1 to tp4 in the circuit data shown in FIG. 1. The type of the test mode which validates the test point tp1 is “Logic BIST” and no “Positional Information” is held. In “Logic BIST” as the test mode for the test point tp1, “Use Purpose” is “Improvement in Transition Probability” and “Effect” is “0.117% Improvement in Transition Probability”. In “Logic BIST” as the test mode for the test point tp1, “Clock Frequency” is 200 MHz, “Logic Synthesis Constraint” is “None”, “Deletable/Undeletable” is “Deletable”, “Effect at Test Points” is “0.191% Improvement in Transition Probability”, and “List of Test Points” related thereto is “{tp4}”. In the information shown in FIG. 2, “Effect at Test Points” indicates test efficiency improved by combining a plurality of test points and the “0.191% Improvement in Transition Probability” mentioned above improves the test efficiency. The test point related to the present test point tp1 for the improved test efficiency is the test point tp4 shown above in “List of Test Points”. “Effect at Test Points” shown herein is “Weighting Information Related to Test Points”

The types of the test modes which validate the test point tp2 are “Scan Test” and “Logic BIST” and no “Positional Information” is held. In “Scan Test” as one of the test modes for the test point tp2, “Use Purpose” is “Improvement in Monitorability” and “Effect” is “10 Nodes”. In “Scan Test” as the test mode for the test point tp2, “Clock Frequency” is “30 MHz”, “Logic Synthesis Constraint” is “False Path”, “Deletable/Undeletable” is “Undeletable”, “Effect at Test Points” is “None”, and “List of Test Points” related thereto is not held. In “Logic BIST” as the other test mode for the test point tp2, “Use Purpose” is “Improvement in Monitorability” and “Effect” is “10 Nodes”. In “Logic BIST” as the test mode for the test point tp2, “Clock Frequency” is “200 MHz”, “Logic Synthesis Constraint” is “None”, “Deletable/Undeletable” is “Undeletable”, “Effect at Test Points” is “None”, and “List of Test Points” related thereto is not held.

The type of the test mode which validates the test point tp3 is “Scan Test” and no “Positional Information” is held. In “Scan Test” as the test mode for the test point tp3, “Use Purpose” is “Reduction in Test Pattern” and “Effect” is “30 Pattern Reduction”. In “Scan Test” as the test mode for the test point tp3, “Clock Frequency” is “30 MHz”, “Logic Synthesis Constraint” is “False Path”, “Deletable/Undeletable” is “Deletable”, “Effect at Test Points” is “None”, and “List of Test Points” related thereto is not held.

The type of the test mode which validates the test point tp4 is “Logic BIST” and no “Positional Information” is held. In “Logic BIST” as the test mode for the test point tp4, “Use Purpose” is “Improvement in Transition Probability” and “Effect” is “0.117% Improvement in Transition Probability”. In “Logic BIST” as the test mode for the test point tp4, “Clock Frequency” is “200 MHz”, “Logic Synthesis Constraint” is “None”, “Deletable/Undeletable” is “Deletable”, “Effect at Test Points” is “0.191% Improvement in Transition Probability”, and “List of Test Points” related thereto is “{tp1}”.

As shown in FIG. 4, the apparatus for designing the semiconductor integrated circuit device is composed of: a data input unit K101 for reading design data D101 as input data; a storage device 700 for storing the read data; a test point deletion unit K104 for deleting an unnecessary test point corresponding only to an unspecified test mode for a test mode D102 as input data about a test mode specified by a computer; and a data output unit K105 for retrieving the design data from the storage device 700 and outputting it. The data input unit K101 is composed of: a code analysis unit K102 for analyzing the code of the design data; and a database storage unit K103 for storing the result of the analysis in the storage device 700. The input data about the test mode specified by the computer indicates data showing specified conditions for given information included in the information about the test mode shown above. Specifically, the given information includes “Positional Information” and information composed of “Type”, “Use Purpose”, “Effect”, “Clock Frequency”, “Logic Synthesis Constraint”, “Deletable/Undeletable”, “Effect at Test Points”, and “List of Test Points” which is included in “Test Mode” of the information about the test mode. The specified conditions indicate “Improvement in Transition Probability” as “Use Purpose”, “0.117% Improvement in Transition Probability” as “Effect” and the like shown in FIGS. 2 and 3 and also include “Logic BIST” as “Type”.

FIG. 8 is a flow chart diagram showing a procedure for test point design according to the first embodiment.

First, in the flow chart, the design data D101 (design data structure) composed of the circuit data on the semiconductor integrated circuit including the test points for the one or plurality of test modes and the information (information about the test mode) attached to the test points in the circuit data is inputted. In Data Read Step S101, the reading of the design data D101 is performed. The reading in Data Read Step S101 is performed in such a manner that the code analysis of the design data D101 is performed first in Code Analysis Step S102 and the result of the analysis is stored in a database in Database Storage Step S103. At this time, the information on the circuit data and the information attached to the test points are entirely analyzed and stored in the database.

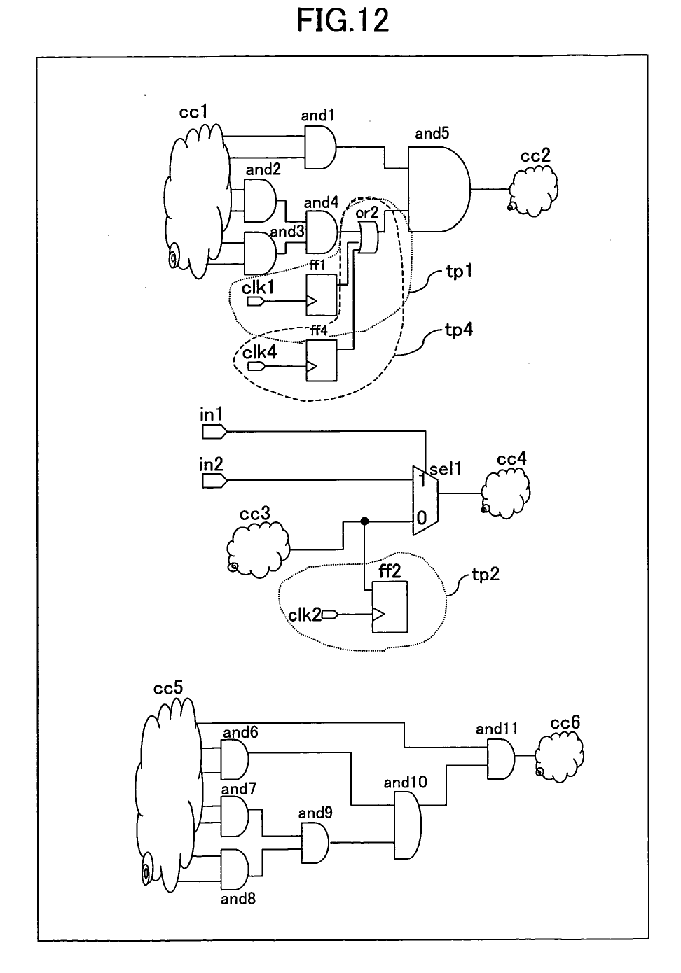

When “Logic BIST” (specified type) indicative of the type is specified as the test mode D102 by the computer, any test point for which “Logic BIST” is not written as “Test Mode” in the information attached to the test point in the circuit data stored in the database is deleted in Test Point Deletion Step S104 so that the test point tp3 is deleted in the present embodiment. Consequently, the flip-flop ff3, the OR circuit or4, and the input terminal clk3 are deleted from the circuit data and the output of the AND circuit and9 is connected to each of the inputs of the AND circuit and10 so that the design data D104 outputted in Data Output Step S105 becomes the circuit shown in FIG. 12.

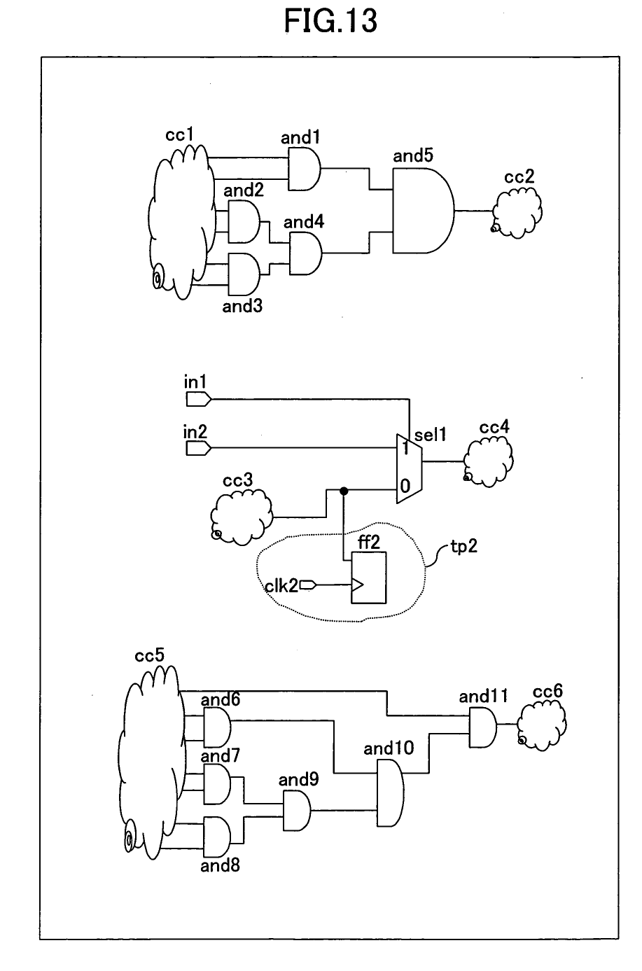

When “Logic BIST” is specified in the test mode D102 and a specified condition such that that “Effect at 1 Test Point” is “0.15%-or-More Improvement in Transition Probability” (Specified Effect) is inputted, any test point for which “Logic BIST” is not written as “Test Mode” in the information attached to the test point is deleted in Test Point Deletion Step S104 so that the test point tp3 is deleted. Even when the type of “Test Mode” is “Logic BIST”, any test point of which “Effect” in the information attached to the test point is a less-than-0.15% improvement in transition probability is deleted so that the test points tp1 and tp4 are deleted and the output design data D103 becomes the circuit shown in FIG. 13. What results is a structure in which, in contrast to the circuit data in the input design data D101, each of the inputs of the AND circuit and5 is connected to the output of the AND circuit and4 and each of the inputs of the AND circuit and10 is connected to the output of the AND circuit and9.

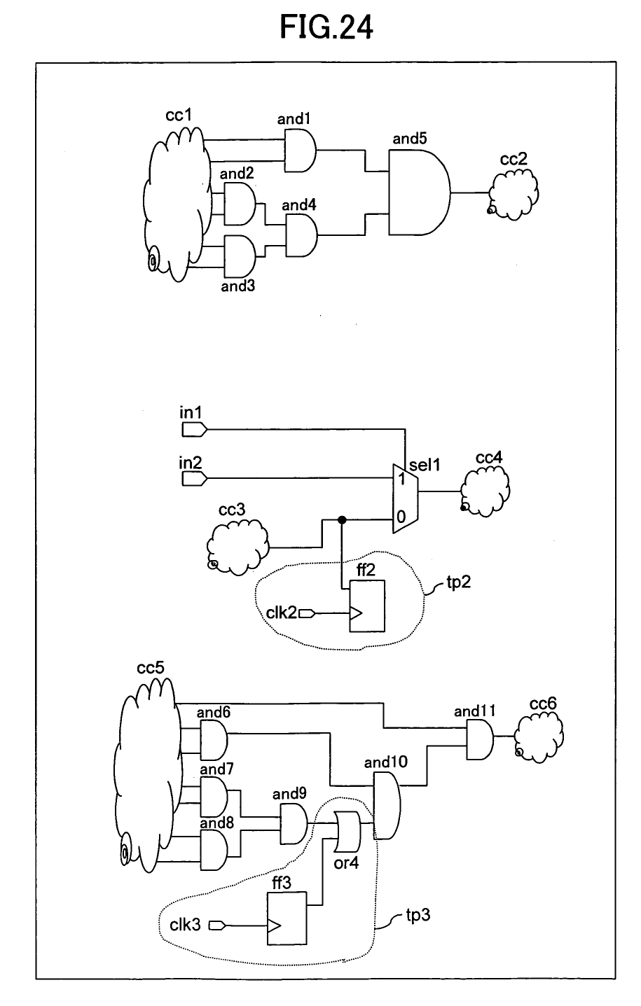

When “Scan Test” is specified as the test mode D102 mentioned above and when “Number of Monitorable Nodes is 15 or More” is specified, any test point of which “Test Mode” is other than “Scan Test” is deleted so that the test points tp1 and tp4 are deleted. Of the test points tp2 and tp3 of each of which “Test Mode” is “Scan Test”, the test point tp2 of which “Use Purpose” is “Number of Monitorable Nodes is 15 or Less” is supposed to be deleted but its “Deletable/Undeletable” as indication information on whether or not the test point may be automatically deletable is “Undeletable” so that the test point tp2 remains without being deleted. As a result, the output design data D103 has a structure as shown in FIG. 24 in which, in contrast to the circuit data in the input design data D101, each of the inputs of the AND circuit and5 is connected to the output of the AND circuit and4.

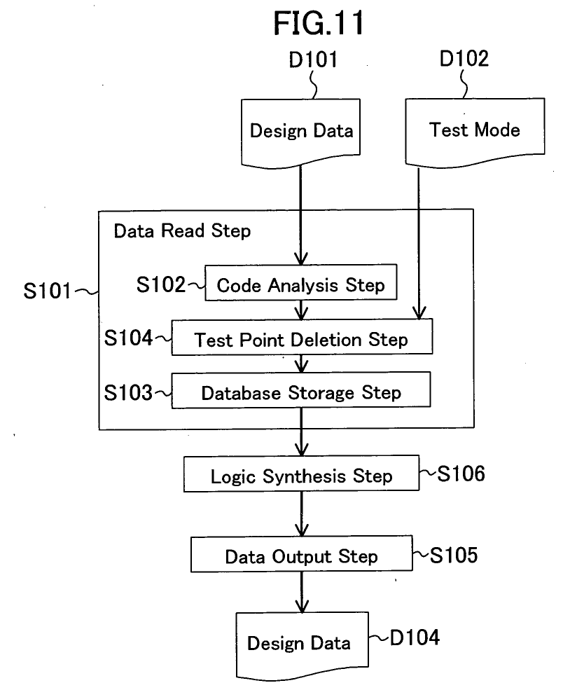

When “Logic BIST” is specified as the test mode D102 mentioned above and a specified condition such that “Effect at Test Points” is “0.18%-or-More Improvement in Transition Probability” (specified effect) is inputted, any test point for which “Logic BIST” is not written as “Test Mode” in the information attached to the test point is deleted so that the test point tp3 is deleted. Even when “Test Mode” is “Logic BIST”, any test point of which “Effect at Test Points” is a 0.18-or-less improvement in transition probability in the information attached to the test point is deleted. Since “Effect at Test Points” in the information held by each of the test points tp1 and tp3 remaining without being deleted is 0.191, the test points tp1 and tp3 remain without being deleted and the circuit data in the output design data becomes the circuit design shown in FIG. 11.

When “Logic BIST” is specified as the test mode D102 mentioned above and a specified condition such that “Effect at Test Points” is “0.20%-or-More Improvement in Transition Probability” is inputted, the test points tp1 and tp3 are deleted since “Effect at Test Points” in the information held by each of the test points tp1 and tp3 is 0.191. As a result, the circuit data in the output design data becomes the circuit data shown in FIG. 13.

### Embodiment 2

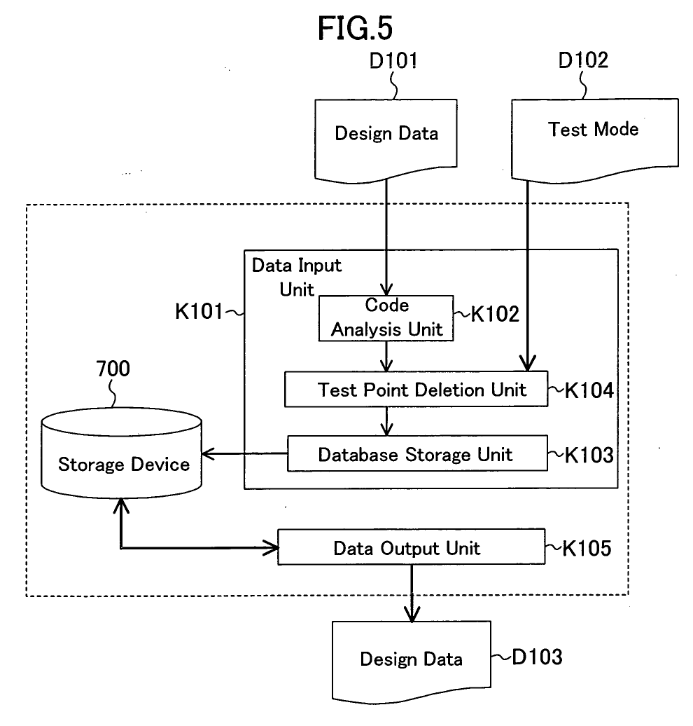

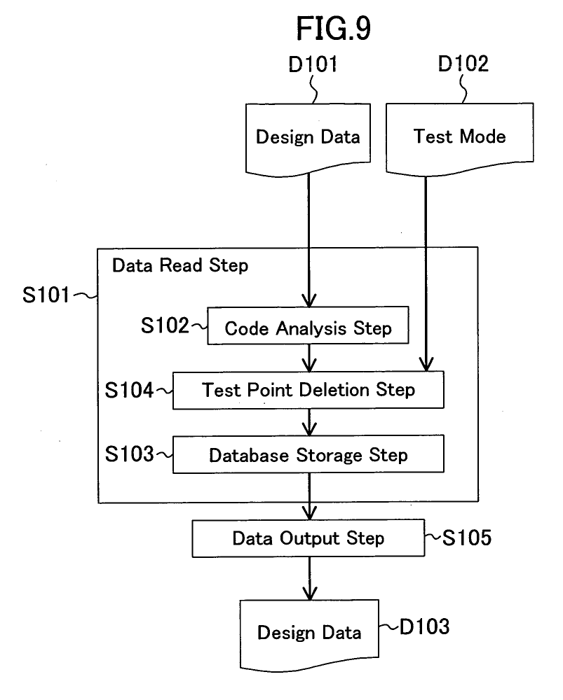

FIG. 5 shows an apparatus for designing a semiconductor integrated circuit according to the second embodiment of the present invention. FIG. 9 is a flow chart diagram showing a procedure for designing a semiconductor integrated circuit by using the apparatus for designing a semiconductor integrated circuit.

As shown in FIG. 5, the apparatus for designing a semiconductor integrated circuit device is composed of: a data input unit K101 for reading design data D101 as input data; a storage device 700 for storing the read data; and a data output unit K105 for outputting design data D103. The data input unit K101 is composed of: a code analysis unit K102 for analyzing the code of the design data; a test point deletion unit K104 for deleting an unnecessary test point for the test mode inputted as a test mode D102; and a database storage unit K103 for storing design data after the deletion of the test point in the storage device 700.

FIG. 9 is a flow chart diagram showing a procedure for test point design according to the second embodiment.

First, in the flow chart, circuit data on a semiconductor integrated circuit including test points for one or a plurality of test modes is inputted as the design data D101 and information attached to the test points in the circuit data is inputted as the test mode D102. In Data Read Step S101, the reading of the design data D101 is performed. The reading is performed in such a manner that the code analysis of the design data D101 is performed first in Code Analysis Step S102. When “Logic BIST”, e.g., is specified as the test mode D102, any test point for which “Logic BIST” is not written as “Test Mode” in the information attached to the test point in the circuit data is deleted in Test Point Deletion Step S104. As a result, circuit data obtained by deleting the test point tp3 from the circuit data is stored in a database in Database Storage Step S103. Then, in Data Output Step S105, the circuit data on the circuit shown in FIG. 12 is outputted as the design data D103.

The second embodiment is different from the first embodiment in that Test Point Deletion Step S104 is provided before Database Storage Step S103. As a result, the test point deleted in Test Point Deletion Step S104 is not stored in the database and therefore cannot be recovered. However, a used space in the memory of the storage device can be reduced.

### Embodiment 3

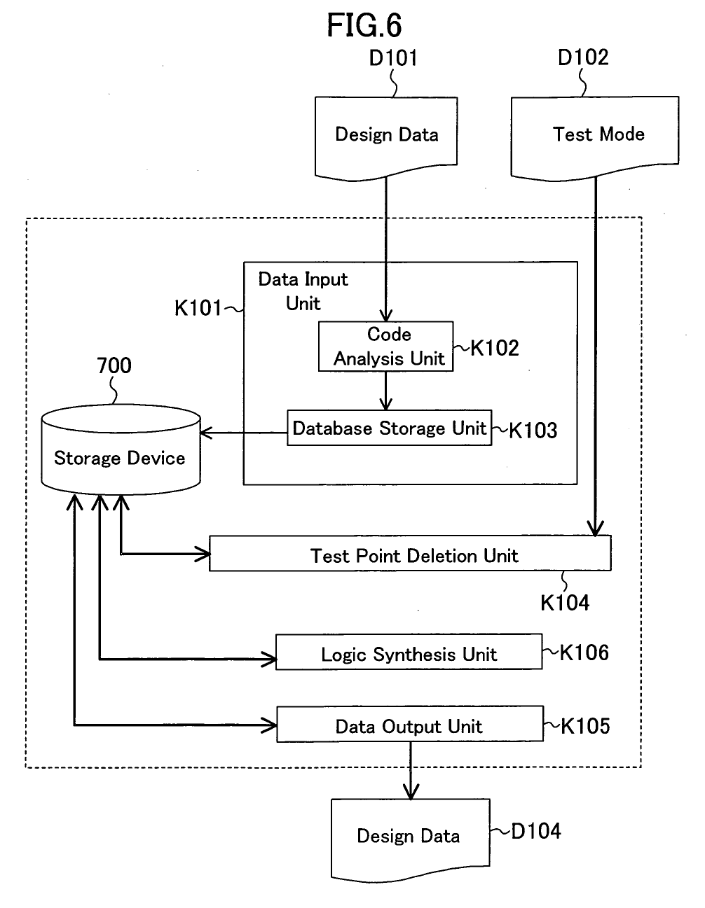

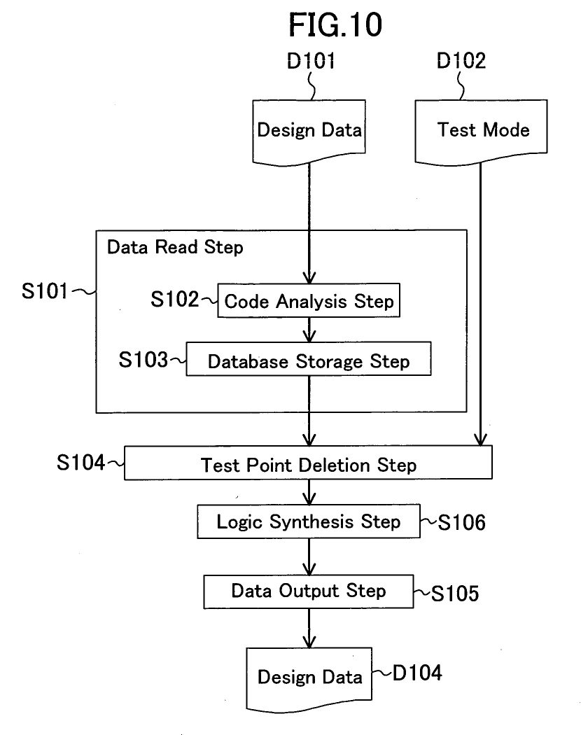

FIG. 6 shows an apparatus for designing a semiconductor integrated circuit according to the third embodiment of the present invention. FIG. 10 is a flow chart diagram showing a procedure for designing a semiconductor integrated circuit by using the apparatus for designing a semiconductor integrated circuit of FIG. 6. The apparatus for designing a semiconductor integrated circuit and the flow chart diagram showing the design procedure according to the present embodiment are basically the same as those described in the first embodiment so that a description will be given to portions different from those in the apparatus for designing the semiconductor integrated circuit and the flow chart diagram showing the design procedure described in the first embodiment.

The apparatus for designing a semiconductor integrated circuit shown in FIG. 6 is different from that described in the first embodiment in that a logic synthesis unit K106 is provided therein. The provision of the logic synthesis unit K106 allows the logic synthesis of the design data stored in the storage device 700 to be performed in Logic Synthesis Step S106. When the input design data D101 is on the RT level, therefore, it becomes possible to output the design data D104 as a net list on the gate level.

### Embodiment 4

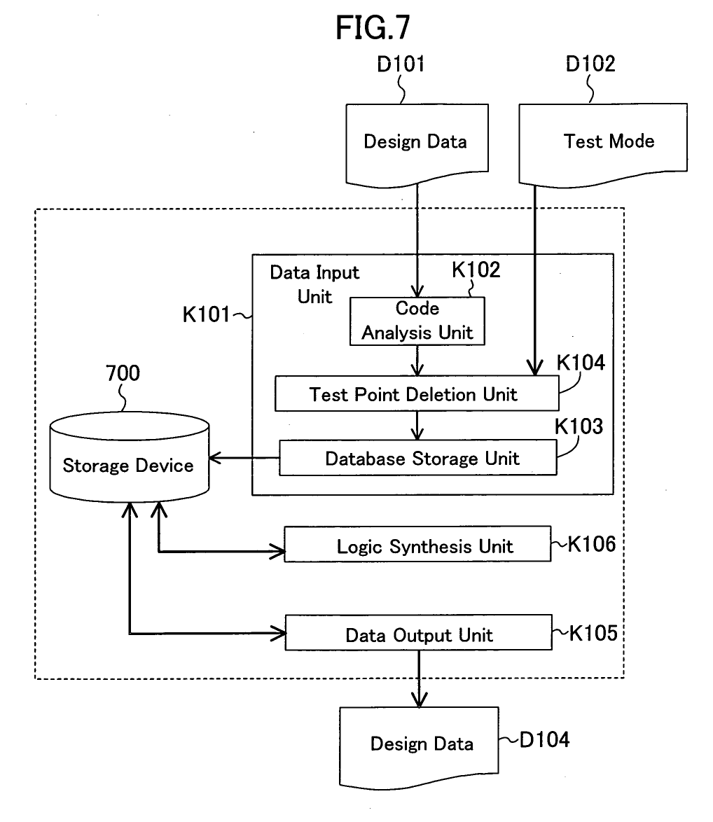

FIG. 7 shows an apparatus for designing a semiconductor integrated circuit according to the fourth embodiment of the present invention. FIG. 11 is a flow chart diagram showing a procedure for designing a semiconductor integrated circuit by using the apparatus for designing a semiconductor integrated circuit. The apparatus for designing a semiconductor integrated circuit and the flow chart diagram showing the design procedure according to the present embodiment are basically the same as those described in the second embodiment so that a description will be given to portions different from those in the apparatus for designing a semiconductor integrated circuit and the flow chart diagram showing the design procedure described in the second embodiment.

The apparatus for designing a semiconductor integrated circuit shown in FIG. 7 is different from that described in the second embodiment in that a logic synthesis unit K106 is provided therein. The provision of the logic synthesis unit K106 allows logic synthesis to be performed in Logic Synthesis Step S106. When the input design data D101 is on the RT level, therefore, it becomes possible to output the design data D104 as a net list on the gate level.

### Embodiment 5

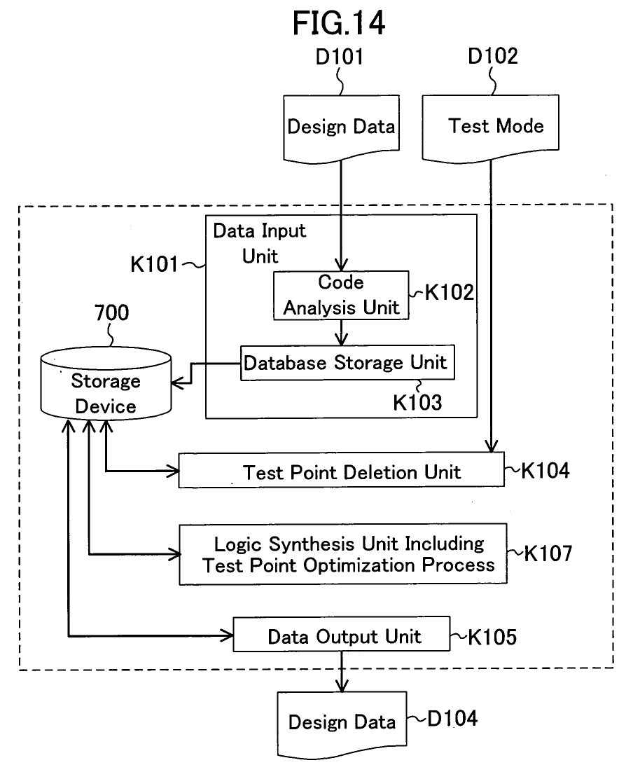

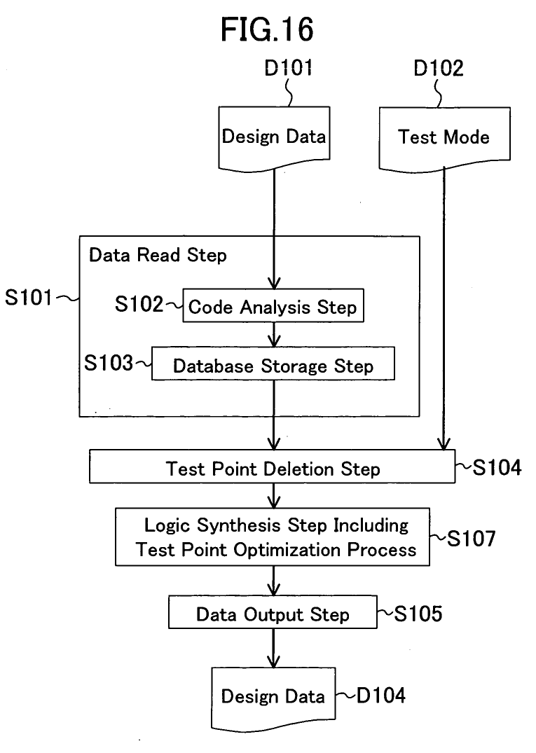

FIG. 14 shows an apparatus for designing a semiconductor integrated circuit according to the fifth embodiment of the present invention. FIG. 16 is a flow chart diagram showing a procedure for designing a semiconductor integrated circuit using the apparatus for designing a semiconductor integrated circuit. The apparatus for designing a semiconductor integrated circuit and the flow chart diagram showing the design procedure according to the present embodiment are basically the same as those described in the third embodiment so that a description will be given to portions different from those in the apparatus for designing a semiconductor integrated circuit and the flow chart diagram showing the design procedure described in the third embodiment.

The apparatus for designing a semiconductor integrated circuit shown in FIG. 14 is different from that described in the third embodiment in that, in contrast to the apparatus for designing a semiconductor integrated circuit described in the third embodiment which has the logic synthesis unit K106, the apparatus for designing a semiconductor integrated circuit according to the present embodiment has a logic synthesis unit K107 including a test point optimization process for performing the optimization of the test points during the logic synthesis process. As shown in FIG. 16, the provision of the logic synthesis unit K107 including the test point optimization process allows the circuit area optimization and timing optimization of a test point circuit to be performed in Logic Synthesis Step S107 including the test point optimization process and thereby allows the design data D104 as a net list on the multi-gate level to be outputted.

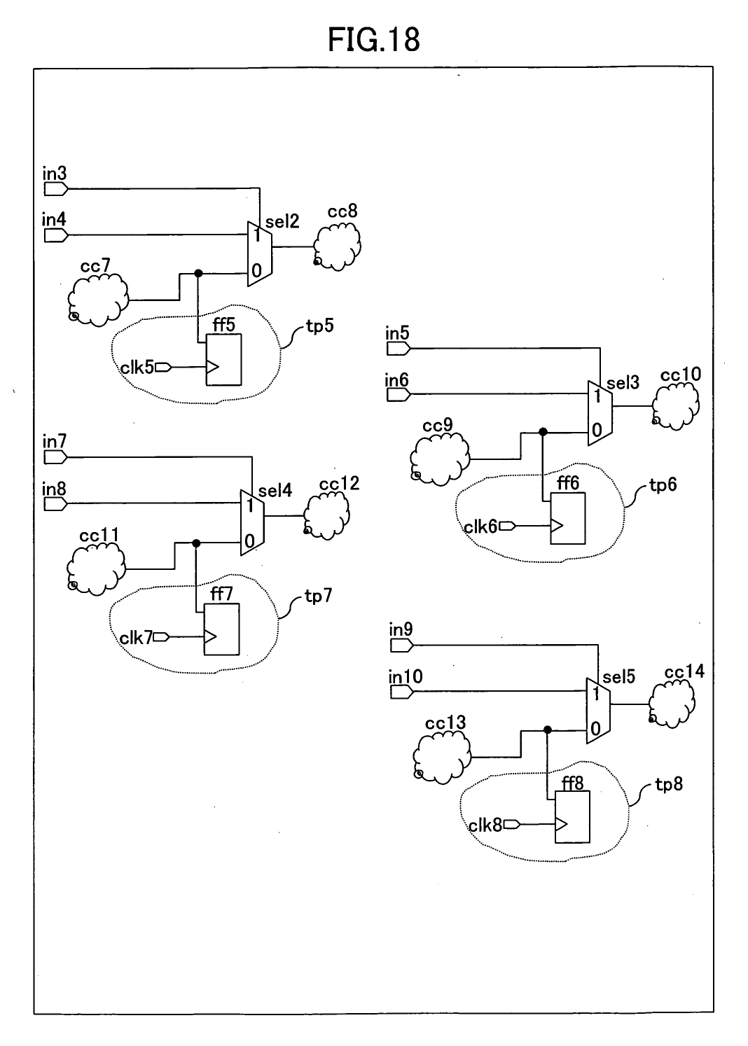

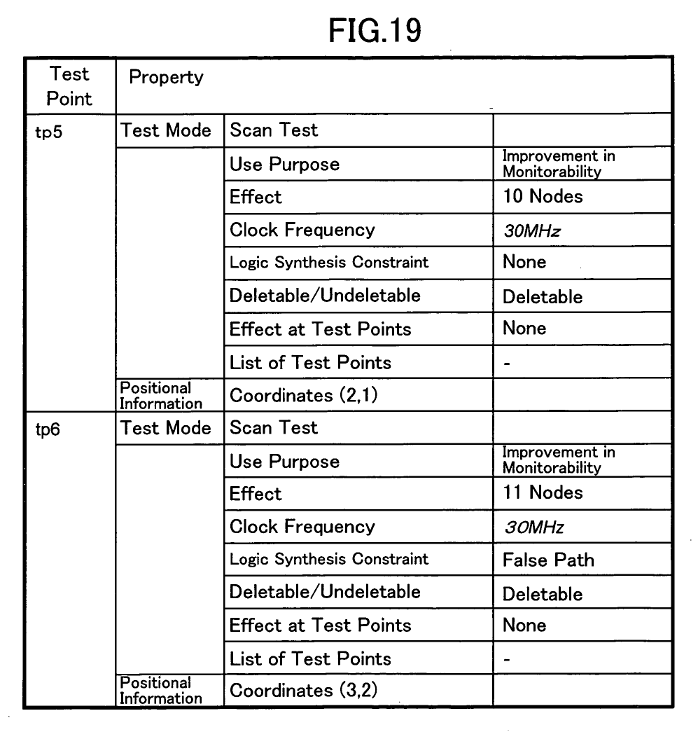

FIG. 18 shows circuit data on a semiconductor integrated circuit including test points for one or a plurality of test modes according to the fifth embodiment. FIG. 19 shows information attached to the test points in the circuit data.

The group of combinational circuits shown in FIG. 18 include eight combinational circuits cc7 to cc14, four selectors sel2 to sel5, four flip-flops ff5 to ff8, and twelve input terminals in3 to in10 and clk5 to clk8.

A description will be given first to the circuit structure between the combinational circuits cc7 and cc8 in the semiconductor integrated circuit shown in FIG. 18. The selector sel2 is controlled by the input terminal in3 such that, when the input value of the input terminal in3 is 1, the input terminal in4 is selected and that, when the input value thereof is 0, the output value of the combinational circuit cc7 is selected. To the clock input of the flip-flop ff5, the input terminal clk5 is connected. To the node between the output of the combinational circuit cc7 and the 0-input of the selector sel2, a test point tp5 composed of the flip-flop ff5 and the input terminal clk5 has been added.

A description will be given next to the circuit structure between the combinational circuits cc9 and cc10. The selector sel3 is controlled by the input terminal in5 such that, when the input value of the input terminal in5 is 1, the input terminal in6 is selected and that, when the input value thereof is 0, the output value of the combinational circuit cc9 is selected. To the clock input of the flip-flop of the flip-flop ff6, the input terminal clk6 is connected. To the node between the output of the combinational circuit cc9 and the 0-input of the selector sel3, a test point tp6 composed of the flip-flop ff6 and the input terminal clk6 has been added.

A description will be given next to the circuit structure between the combinational circuits cc11 and cc12. The selector sel4 is controlled by the input terminal in7 such that, when the input value of the input terminal in7 is 1, the input terminal in8 is selected and that, when the input value thereof is 0, the output value of the combinational circuit cc1 is selected. To the clock input of the flip-flop ff7, the input terminal clk7 is connected. To the node between the output of the combinational circuit cc11 and the 0-input of the selector sel4, a test point tp7 composed of the flip-flop ff7 and the input terminal clk7 has been added.

Subsequently, a description will be given to the circuit structure between the combinational circuits cc13 and cc14. The selector sel5 is controlled by the input terminal in9 such that, when the input value of the input terminal in9 is 1, the input terminal in10 is selected and that, when the input value thereof is 0, the output value of the combinational circuit cc13 is selected. To the clock input of the flip-flop ff8, the input terminal clk8 is connected. To the node between the output of the combinational circuit cc13 and the 0-input of the selector sel5, a test point tp8 composed of the flip-flop ff8 and the input terminal clk8 has been added.

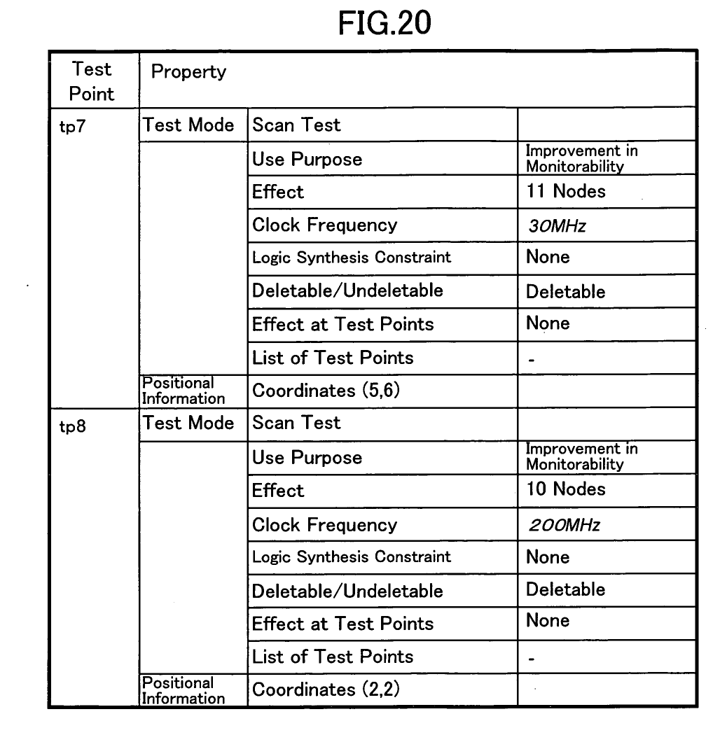

FIG. 19 shows information attached to the test points tp5 and tp6 added to the circuit data. FIG. 20 shows information attached to the test points tp7 and tp8 added to the circuit data. Each of the test points tp5 to tp8 holds “Test Mode” and “Positional Information” as information (information about the test mode) associated therewith. Each “Test Mode” holds information composed of “Use Purpose”, “Effect”, “Clock Frequency”, “Logic Synthesis Constraint”, “Deletable/Undeletable”, “Effect at Test Points”, and “List of Test Points”.

The test mode for the test point tp5 is “Scan Test” and holds the coordinates (2,1) as “Positional Information”. In “Scan Test” as the test mode for the test point tp5, “Use Purpose” is “Improvement in Monitorability” and “Effect” is “10 Nodes”. In “Scan Test” as the test mode for the test point tp5, “Clock Frequency” is “30 MHz”, “Logic Synthesis Constraint” is “None”, “Deletable/Undeletable” is “Deletable”, and “Effect at Test Points” is “None”.

The test mode for the test point tp6 is “Scan Test” and holds the coordinates (3,2) as “Positional Information”. In “Scan Test” as the test mode for the test point tp6, “Use Purpose” is “Improvement in Monitorability” and “Effect” is “11 Nodes”. In “Scan Test” as the test mode for the test point tp6, “Clock Frequency” is “30 MHz”, “Logic Synthesis Constraint” is “False Path”, “Deletable/Undeletable” is “Deletable”, and “Effect at Test Points” is “None”.

The test mode for the test point tp7 is “Scan Test” and holds the coordinates (5,6) as “Positional Information”. In “Scan Test” as the test mode for the test point tp7, “Use Purpose” is “Improvement in Monitorability” and “Effect” is “11 Nodes”. In “Scan Test” as the test mode for the test point tp7, “Clock Frequency” is “30 MHz”, “Logic Synthesis Constraint” is “None”, “Deletable/Undeletable” is “Deletable”, and “Effect at Test Points” is “None”.

The test mode for the test point tp8 is “Scan Test” and holds the coordinates (2,2) as “Positional Information”. In “Scan Test” as the test mode for the test point tp8, “Use Purpose” is “Improvement in Monitorability” and “Effect” is “10 Nodes”. In “Scan Test” as the test mode for the test point tp8, “Clock Frequency” is “200 MHz”, “Logic Synthesis Constraint” is “None”, “Deletable/Undeletable” is “Deletable”, and “Effect at Test Points” is “None”.

FIG. 16 is a flow chart diagram showing a procedure for test point design according to the fifth embodiment.

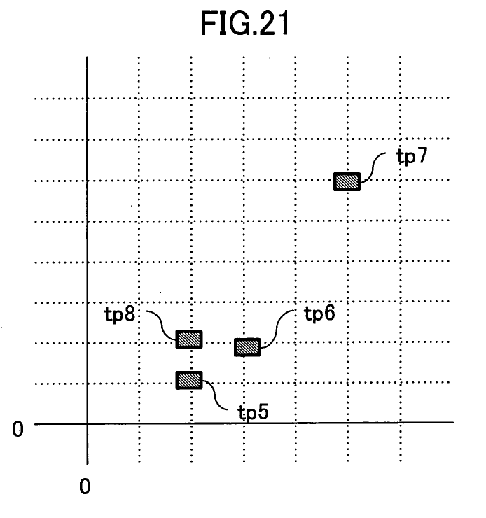

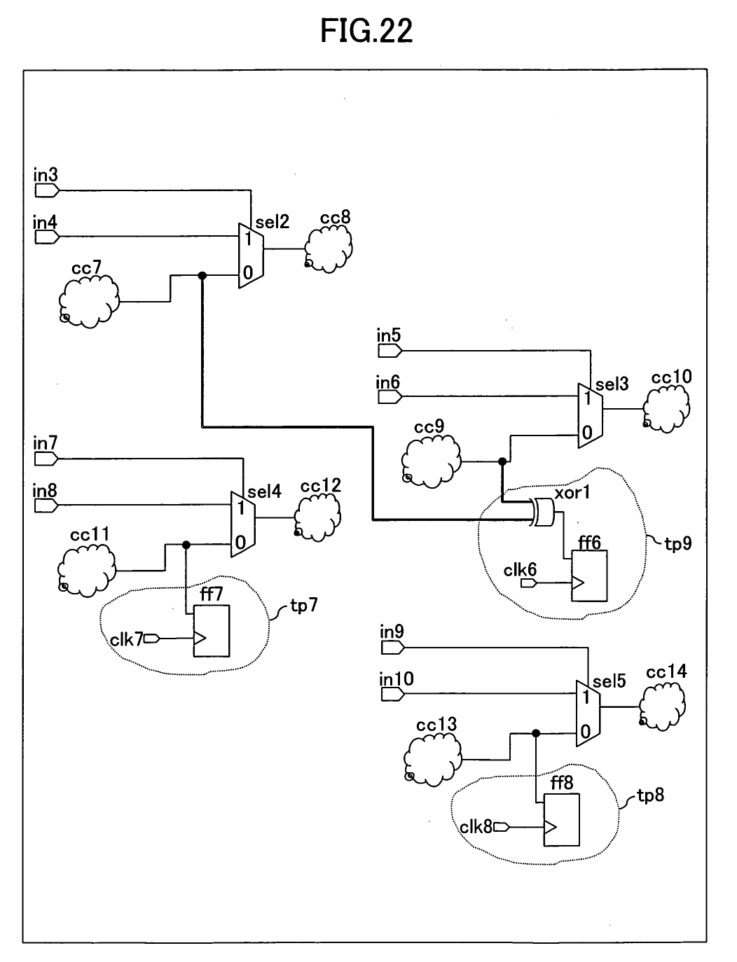

First, the circuit data on the semiconductor integrated circuit including the test points for the one or plurality of test modes shown in FIG. 18 and the information attached to the test points in the circuit data shown in FIGS. 19 and 20 are inputted as the design data D101. FIG. 21 is the coordinate representation of “Positional Information” included in the information attached to the test points in the circuit data. In Data Read Step D102, the reading of the design data D101 is performed. When conditions such that the type of the test mode is “Scan Test” and “Test Point Merging Distance is 5 or Less in Manhattan Distance” are specified in the test mode D102, any test point for which “Scan Test” is not written as “Test Mode” in the information attached to the test point in the circuit data stored in the database is deleted in Test Point Deletion Step S102. However, since the design data D101 has no test point for which “Test Mode” is other than “Scan Test”, no test point is deleted in Test Point Deletion Step S104. Then, in Logic Synthesis Step S105 as the next step including a test point optimization process, timing optimization is performed based on the logic synthesis constraints included in “Logic Synthesis Constraints” in the information attached to the test points in the circuit data, while test point merging is performed under the condition that “Test Point Merging Distance is 5 or Less in Manhattan Distance” specified as the test mode D102. A list of candidate test points which can be merged include the test points {tp5, tp6, and tp7} of which the input clocks have the same frequency. When the Manhattan distance between a combination of each two of the mergeable test points in the list is determined, the Manhattan distance |tp5-tp6| between the test points tp5 and tp6 is 2, the Manhattan distance |tp5-tp7| between the test points tp5 and tp7 is 8, and the Manhattan distance |tp6-tp7| between the test points tp6 and tp7 is 6. Since the condition specified in the test mode D102 is “Test Point Merging Distance is 5 or Less in Manhattan Distance”, the test points tp5 and tp6 which satisfy the condition are judged to be mergeable so that they are merged. Since the design data D104 outputted in Data Output Step S105 assigns the function of “Improvement in Monitorability” that has been performed by the flip-flop ff5 to the flip-flop ff6 as shown in FIG. 22, a circuit is provided from which the test point tp5 composed of the flip-flop ff5 and the input terminal clk5 has been deleted, to which an XOR circuit xor1 has been added, and in which the outputs of the combinational circuits cc7 and cc9 are connected to the inputs of the XOR circuit xor1, and the output of the XOR circuit xor1 is connected to the input of the flip-flop ff6.

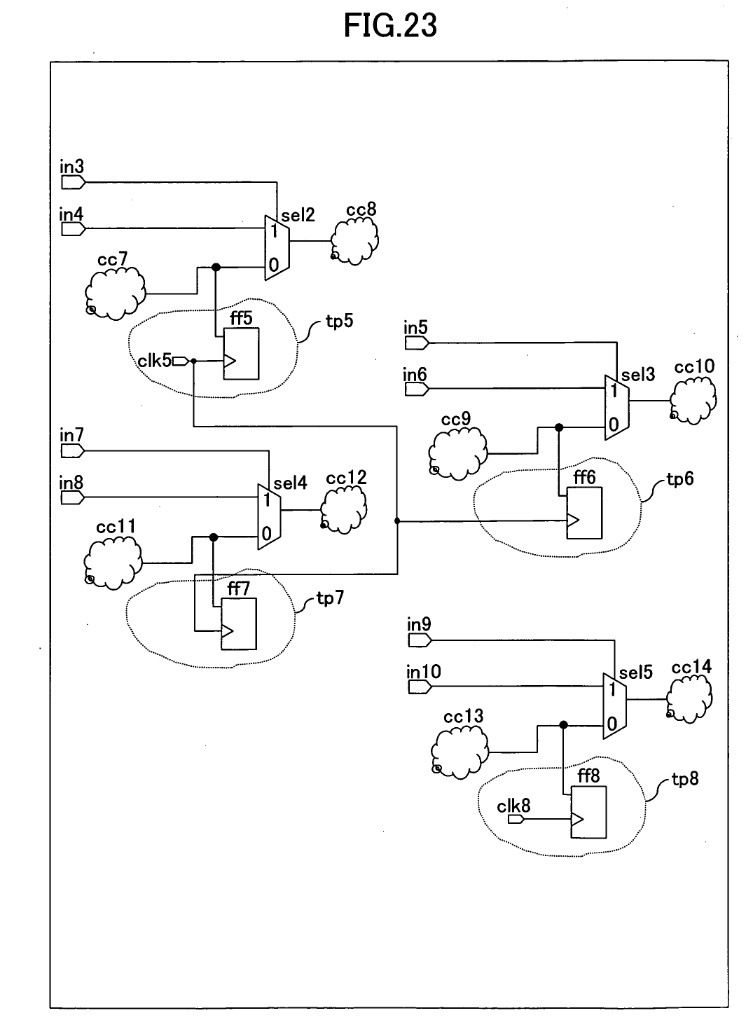

When “Scan Test” is specified as the test mode D102 and “Clock Source Sharing” is inputted, clocks having the same use purpose and the same frequency are shared. In the case with the design data D101, a list of the test points which can share a clock source are {tp5, tp6, and tp7}. In the design data D104 outputted in Data Output Step S105, the input terminals clk6 and clk7 are deleted and each of the clock inputs of the flip-flops ff6 and ff7 is connected to the input terminal clk5, as shown in FIG. 23.

The Manhattan distance described herein can be measured between any two nodes as follows. The differences between the values of the same coordinate components of the two nodes are determined individually and the absolute values of the differences between the same coordinate components are added up on a component-by-component basis. The sum of the absolute values of the differences therebetween is the Manhattan distance.

### Embodiment 6

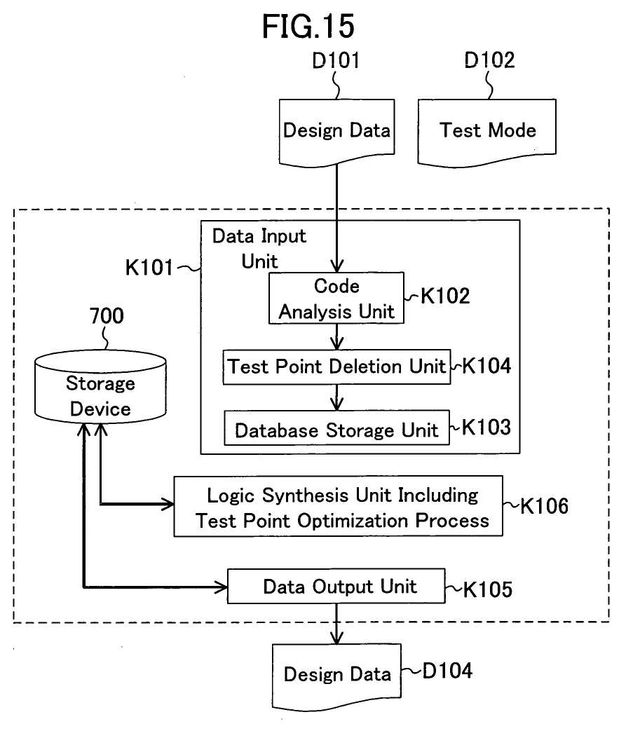

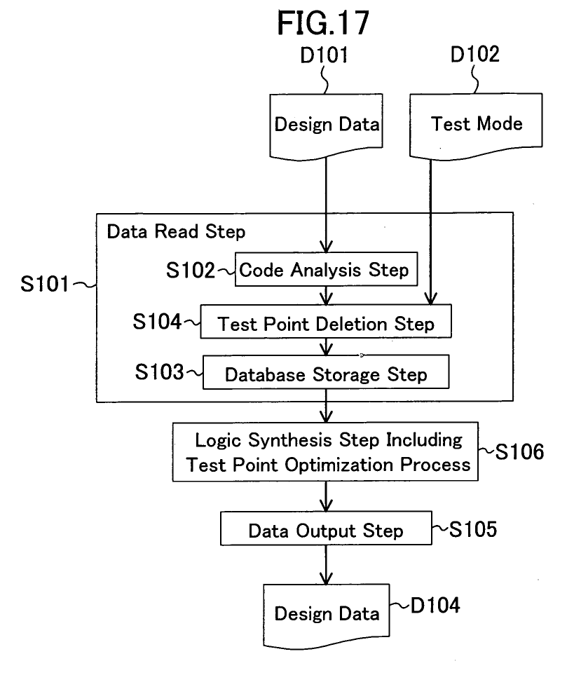

FIG. 15 shows an apparatus for designing a semiconductor integrated circuit according to a sixth embodiment of the present invention. FIG. 17 is a flow chart diagram showing a procedure for designing a semiconductor integrated circuit by using the apparatus for designing a semiconductor integrated circuit. The apparatus for designing a semiconductor integrated circuit and the flow chart diagram showing the design procedure according to the present embodiment are basically the same as those described in the fifth embodiment so that a description will be given to portions different from those in the apparatus for designing a semiconductor integrated circuit and the flow chart diagram showing the design procedure described in the fifth embodiment.

The apparatus for designing a semiconductor integrated circuit shown in FIG. 15 is different from that described in the fifth embodiment in that the test point deletion unit K104 is provided within the data input unit. By using the apparatus for designing a semiconductor integrated circuit to delete a test point in Test Point Deletion Step S104 in a stage previous to Database Storage Step S103, a used space in the memory of the storage device can further be reduced than in the fifth embodiment.

What is claimed is:

1. A design data structure for a semiconductor integrated circuit which is for use in design of a semiconductor integrated circuit using a computer, the design data structure comprising:
circuit data on at least one test point added to a specified node in the semiconductor integrated circuit as a target of design for testability; and
information about at least one test mode associated with the circuit data on the test point to validate the test point, wherein
when the computer specifies the test mode about which the information includes given information which satisfies a specified condition, an unnecessary test point which does not have the given information satisfying the specified condition is invalidated.

2. An apparatus for designing a semiconductor integrated circuit using the design data structure of claim 1, the apparatus comprising:
a data input unit comprising a design data code analysis unit for reading the design data structure and analyzing a code of design data included in the design data structure and composed of the circuit data on the semiconductor integrated circuit and on the test point and of the information about the test mode and a database storage unit for storing a result of the analysis by the design data code analysis unit in a database;
a test point deletion unit for deleting the unnecessary test point at which the specified condition indicated by the computer is not satisfied from the result of the analysis stored in the database; and
a circuit data output unit for outputting circuit data on the test point remaining as a result of the deletion of the unnecessary test point by the test point deletion unit and on the semiconductor integrated circuit.

3. An apparatus for designing a semiconductor integrated circuit using the design data structure of claim 1, the apparatus comprising:
a data input unit comprising a design code analysis unit for reading the design data structure and analyzing a code of design data included in the design data structure and composed of the circuit data on the semiconductor integrated circuit and on the test point and of the information about the test mode, a test point deletion unit for deleting the unnecessary test point at which the specified condition indicated by the computer is not satisfied from a result of the analysis by the design data code analysis unit, and a database storage unit for storing a result of the deletion in a database; and
a circuit data output unit for outputting the circuit data on the test point remaining as the result of the deletion of the unnecessary test point by the test point deletion unit and on the semiconductor integrated circuit which has been stored in the database by the database storage unit.

4. The apparatus for designing a semiconductor integrated circuit of claim 2, further comprising:
a logic synthesis unit for performing a logic synthesis process with respect to the circuit data on the semiconductor integrated circuit and on the test point which has been stored in the database and storing a result of the logic synthesis process in the database.

5. The apparatus for designing a semiconductor integrated circuit of claim 3, further comprising:
a logic synthesis unit for performing a logic synthesis process with respect to the circuit data on the semiconductor integrated circuit and on the test point which has been stored in the database and storing a result of the logic synthesis process in the database.

6. A method for designing a semiconductor integrated circuit using the design data structure of claim 1, the method comprising:
a circuit data read step including a design data code analysis step of reading the design data structure and analyzing a code of design data included in the design data structure and composed of the circuit data on the semiconductor integrated circuit and on the test point and of the information about the test mode and a database storage step of storing a result of the analysis by the design data code analysis step in a database;
a test point deletion step of deleting the unnecessary test point at which the specified condition indicated by the computer is not satisfied from the result of the analysis stored in the database; and
a circuit data output step of outputting circuit data on the test point remaining as a result of the deletion of the unnecessary test point by the test point deletion step and on the semiconductor integrated circuit.

7. A method for designing a semiconductor integrated circuit using the design data structure of claim 1, the method comprising:
a circuit data read step including a design code analysis step of reading the design data structure and analyzing a code of design data included in the design data structure and composed of the circuit data on the semiconductor integrated circuit and on the test point and of the information about the test mode, a test point deletion step of deleting the unnecessary test point at which the specified condition indicated by the computer is not satisfied from a result of the analysis by the design data code analysis step, and a database storage step of storing a result of the deletion in a database; and
a circuit data output step of outputting the circuit data on the test point remaining as the result of the deletion of the unnecessary test point in the test point deletion step and on the semiconductor integrated circuit which has been stored in the database in the database storage step.

8. A method for designing a semiconductor integrated circuit using the design data structure of claim 1, the method comprising:
a circuit data read step including a design data code analysis step of reading the design data structure and analyzing a code of design data included in the design data structure and composed of the circuit data on the semiconductor integrated circuit and on the test point and of the information about the test mode and a database storage step of storing a result of the analysis by the design data code analysis step in a database;
a test point deletion step of deleting the unnecessary test point at which the specified condition indicated by the computer is not satisfied from the result of the analysis stored in the database;
a logic synthesis step of performing a logic synthesis process with respect to circuit data on the test point remaining as a result of the deletion of the unnecessary test point in the test point deletion step and on the semiconductor integrated circuit; and
a circuit data output step of outputting the circuit data on the remaining test point and on the semiconductor integrated circuit to which the logic synthesis process has been performed in the logic synthesis step.

9. A method for designing a semiconductor integrated circuit using the design data structure of claim 1, the method comprising:
a circuit data read step including a design code analysis step of reading the design data structure and analyzing a code of design data included in the design data structure and composed of the circuit data on the semiconductor integrated circuit and on the test point and of the information about the test mode, a test point deletion step of deleting the unnecessary test point at which the specified condition indicated by the computer is not satisfied from a result of the analysis in the design data code analysis step, and a database storage step of storing a result of the deletion in a database;
a logic synthesis step of performing a logic synthesis process with respect to circuit data on the test point remaining as a result of the deletion of the unnecessary test point in the test point deletion step and stored in the database in the database storage step and on the semiconductor integrated circuit; and
a circuit data output step of outputting the circuit data on the remaining test point and on the semiconductor integrated circuit to which the logic synthesis process has been performed in the logic synthesis step.

10. The design data structure of claim 1, wherein
the information about the test mode includes type information indicative of a type of the test mode associated with the circuit data on the test point and
the computer specifies the test mode of a specified type in respect of the type information included in the information about the test mode and invalidates the unnecessary test point which does not correspond to the test mode having the type information of the specified type.

11. The method for designing a semiconductor integrated circuit of claim 6, wherein
the information about the test mode includes type information indicative of a type of the test mode associated with the circuit data on the test point and
the test point deletion step includes deleting, when the computer specifies the test mode showing a specified type in respect of the type information, the unnecessary test point for the test mode which does not include the type information of the specified type that has been specified by the computer.

12. The design data structure of claim 1, wherein
the information about the test mode includes effect information indicative of an effect associated with the circuit data on the test point and suited to a use purpose of the test mode and
the computer specifies the test mode having a specified effect in respect of the effect information included in the information about the test mode and invalidates the unnecessary test point which does not correspond to the test mode having the effect information showing the specified effect.

13. The method for designing a semiconductor integrated circuit of claim 6, wherein the test point deletion step includes deleting the test point having a small effect compared with an area increase based on effect information included in the test point.

14. The design data structure of claim 1, wherein
the information about the test mode includes indication information associated with the circuit data on the test point and indicative of whether or not the test point may be automatically deleted and
when the computer specifies indication information permitting the automatic deletion in respect of the indication information included in the information about the test mode, the unnecessary test point corresponding to the test mode including the specified indication information is invalidated.

15. The method for designing a semiconductor integrated circuit of claim 6, wherein the test point deletion step includes deleting the test point having a small effect compared with an area increase based on the indication information on whether or not the test point may be automatically deleted.

16. The design data structure of claim 1, wherein
the information about the test mode includes weighting information which is information associated with the circuit data on the test point and related to the plurality of test points in each of which it is included and
when the computer specifies the test mode which does not include given weighting information in respect of the weighting information included in the information about the test mode, the unnecessary test point corresponding to the specified test mode is invalidated.

17. The method for designing a semiconductor integrated circuit of claim 6, wherein
the information about the test mode includes weighting information which is information associated with the circuit data on the test point and related to the plurality of test points in each of which it is included and the test point deletion step includes deleting the test point corresponding to the test mode of which the weighting information does not include given weighting information specified by the computer.

18. The design data structure of claim 1, wherein the computer optimizes the test point corresponding to the test mode having the given information which satisfies the specified condition indicated thereby.

19. An apparatus for designing a semiconductor integrated circuit using the design data structure of claim 18, the apparatus comprising:
a data input unit comprising a design data code analysis unit for reading the design data structure and analyzing a code of design data included in the design data structure and composed of the circuit data on the semiconductor integrated circuit and on the test point and of the information about the test mode and a database storage unit for storing a result of the analysis by the design data code analysis unit in a database;
a test point deletion unit for deleting the unnecessary test point at which the specified condition indicated by the computer is not satisfied from the result of the analysis stored in the database;
a logic synthesis unit for performing a logic synthesis process involving optimization of the test point corresponding to the test mode having the given information which satisfies the specified condition indicated by the computer and storing a result of the logic synthesis process in the database; and
a circuit data output unit for outputting, from the database, the circuit data on the test point remaining as a result of the deletion of the unnecessary test point by the test point deletion unit and on the semiconductor integrated circuit.

20. An apparatus for designing a semiconductor integrated circuit using the design data structure of claim 18, the apparatus comprising:
a data input unit comprising a design code analysis unit for reading the design data structure and analyzing a code of design data included in the design data structure and composed of the circuit data on the semiconductor integrated circuit and on the test point and of the information about the test mode, a test point deletion unit for deleting the unnecessary test point at which the specified condition indicated by the computer is not satisfied from a result of the analysis by the design data code analysis unit, and a database storage unit for storing a result of the deletion in a database;
a logic synthesis unit for performing a logic synthesis process involving optimization of the test point corresponding to the test mode having the given information which satisfies the specified condition indicated by the computer and storing a result of the logic synthesis process in the database; and
a circuit data output unit for outputting, from the database, the circuit data on the test point remaining as the result of the deletion of the unnecessary test point by the test point deletion unit and on the semiconductor integrated circuit which has been stored in the database by the database storage unit.

21. A method for designing a semiconductor integrated circuit using the design data structure of claim 18, the method comprising:
a circuit data read step including a design data code analysis step of reading the design data structure and analyzing a code of design data included in the design data structure and composed of the circuit data on the semiconductor integrated circuit and on the test point and of the information about the test mode and a database storage step of storing a result of the analysis by the design data code analysis step in a database;
a test point deletion step of deleting the unnecessary test point at which the specified condition indicated by the computer is not satisfied from the result of the analysis stored in the database;
a logic synthesis step of performing a logic synthesis process involving optimization of the test point corresponding to the test mode having the given information which satisfies the specified condition indicated by the computer and storing a result of the logic synthesis process in the database; and
a circuit data output step of outputting, from the database, the circuit data on the test point remaining as a result of the deletion of the unnecessary test point by the test point deletion step and on the semiconductor integrated circuit.

22. A method for designing a semiconductor integrated circuit using the design data structure of claim 18, the method comprising:
a circuit data read step including a design code analysis step of reading the design data structure and analyzing a code of design data included in the design data structure and composed of the circuit data on the semiconductor integrated circuit and on the test point and of the information about the test mode, a test point deletion step of deleting the unnecessary test point at which the specified condition indicated by the computer is not satisfied from a result of the analysis in the design data code analysis step, and a database storage step of storing a result of the deletion in a database;
a logic synthesis step of performing a logic synthesis process involving optimization of the test point corresponding to the test mode having the given information which satisfies the specified condition indicated by the computer and storing a result of the logic synthesis process in the database; and
a circuit data output step of outputting, from the database, the circuit data on the test point remaining as the result of the deletion of the unnecessary test point by the test point deletion step and on the semiconductor integrated circuit which has been stored in the database by the database storage step.

23. The design data structure of claim 18, the design data structure including positional information associated with the circuit data on the test point and showing a position of the test point, wherein
the computer performs optimization of the test point corresponding to the test mode having the given information which satisfies the specified condition by using the positional information on the test point.

24. The method for designing a semiconductor integrated circuit of claim 21, the method including positional information associated with the circuit data on the test point and showing a position of the test point, wherein
the logic synthesis step includes performing the logic synthesis process involving optimization through merging of the test point corresponding to the test mode having the given information which satisfies the specified condition by using the positional information on the test point.

25. The design data structure of claim 18, wherein
the information about the test mode includes clock frequency information associated with the circuit data on the test point and
the computer performs optimization of the test point based on the clock frequency information.

26. The method for designing a semiconductor integrated circuit of claim 21, wherein
the information about the test mode includes clock frequency information associated with the circuit data on the test point and
the logic synthesis step includes performing the logic synthesis process involving optimization through sharing of a clock source based on the clock frequency information.

27. The design data structure of claim 18, wherein
the information about the test mode includes logic synthesis constraint information associated with the circuit data on the test point and
the computer performs optimization of the test point based on the logic synthesis constraint information.

28. The method for designing a semiconductor integrated circuit of claim 21, wherein
the information about the test mode includes logic synthesis constraint information associated with the circuit data on the test point and
the logic synthesis step includes performing the logic synthesis process involving optimization of timing based on the logic synthesis constraint information.
